(19) United States
(12) Patent Application Publication
(10) Pub. No.: US 2026/0371872 A1
(43) Pub. Date: Nov. 19, 2026

(54) DISPLAY DEVICE, METHOD FOR MANUFACTURING THE SAME AND ELECTRONIC DEVICE

(71) Applicant: Samsung Display Co., Ltd., Yongin-si (KR)

(72) Inventors: Ji Sun KIM, Yongin-si (KR); Sun Hwa LEE, Yongin-si (KR); Kyung Hoon CHUNG, Yongin-si (KR); Kwi Hyun KIM, Yongin-si (KR); Se Hyun LEE, Yongin-si (KR)

(21) Appl. No.: 19/464,290

(22) Filed: Jan. 29, 2026

(30) Foreign Application Priority Data
May 13, 2025 (KR) 10-2025-0061782

(51) Int. Cl. H10K 59/131

(52) U.S. Cl. CPC H10K 59/131

(57) ABSTRACT

A display device includes a substrate including a display area and a non-display area; pixels in the display area; a scan driving portion configured to apply scan signals to the plurality of pixels and is located in the non-display area; a first power supply bus line in the non-display area and is arranged closer to the display area than the scan driving portion is, the first power supply bus line being around the display area and electrically connected to the pixels; and a second power supply bus line in the non-display area and is arranged farther from the display area than the scan driving portion is, the second power supply bus line being around the first power supply bus line, the first power supply bus line and the second power supply bus line are branched from one power supply line and are electrically connected to each other.

### CROSS-REFERENCE TO RELATED APPLICATION

The present application claims priority to and the benefit of Korean Patent Application No. 10-2025-0061782, filed on May 13, 2025, in the Korean Intellectual Property Office, the entire disclosure of which is incorporated by reference herein.

### BACKGROUND

### 1. Field

The present disclosure relates to a display device and an electronic device including the same.

### 2. Description of the Related Art

With the development of the information society, the demand for display devices for displaying images is increasing in various forms. The display device may be a flat panel display such as a liquid crystal display, a field emission display, a light emitting display, and/or the like.

The light emitting display device may be implemented as an organic light emitting display device including an organic light emitting diode (OLED) element as the light emitting element, an inorganic light emitting display device including an inorganic semiconductor element as the light emitting element, or a ultra-small light emitting diode display device including a ultra-small light emitting diode element (or micro light emitting diode element) as the light emitting element.

### SUMMARY

Aspects and features of embodiments of the present disclosure are to provide a display device capable of reducing the voltage drop of the driving voltage transmitted to pixels and an electronic device including the same.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments a display device including: a substrate including a display area and a non-display area; a plurality of pixels in the display area; a scan driving portion configured to apply scan signals to the plurality of pixels and is located in the non-display area; a first power supply bus line in the non-display area and is arranged closer to the display area than the scan driving portion is, the first power supply bus line being around the display area and electrically connected to the pixels; and a second power supply bus line in the non-display area and is arranged farther from the display area than the scan driving portion is, the second power supply bus line being around the first power supply bus line, wherein the first power supply bus line and the second power supply bus line are branched from one power supply line and are electrically connected to each other.

According to one or more embodiments, wherein a top and bottom of the scan driving portion is completely surrounded by the first power supply bus line and the second power supply bus line.

According to one or more embodiments, a pixel of the plurality of pixels includes: a common electrode and a plurality of pixel electrodes on the substrate; and a plurality of light emitting elements electrically connected between the plurality of pixel electrodes and the common electrode, wherein the common electrode is electrically connected to the first power supply bus line.

According to one or more embodiments, further including an anti-static circuit located on a top side of the display area, wherein the anti-static circuit is located between the first power supply bus line and the second power supply bus line.

According to one or more embodiments, further including a power supply connection electrode that connects the first power supply bus line and the second power supply bus line and covers an area between the scan driving portion and the first power supply bus line, and an area between the scan driving portion and the second power supply bus line, and covers the scan driving portion.

According to one or more embodiments, the power supply connection electrode has a plurality of hole patterns penetrating the power supply connection electrode in at least one of the scan driving portion, between the first power supply bus line and the scan driving portion, and between the scan driving portion and the second power supply bus line.

According to one or more embodiments, the power supply connection electrode is on a same layer as pixel electrodes and a common electrode in the plurality of pixels and is electrically connected to the common electrode.

According to one or more embodiments, the display device further including: a first line connection electrode in the non-display area and located between the first power supply bus line and the power supply connection electrode, and a second line connection electrode in the non-display area and located between the second power supply bus line and the power supply connection electrode.

According to one or more embodiments, the common electrode is electrically connected to the second line connection electrode.

According to one or more embodiments,

10. The display device of claim 1, the pixels are arranged along a first direction and a second direction in the display area, wherein the pixels of each horizontal line arranged along the first direction among the pixels share one common electrode extending in the first direction, wherein the common electrodes of the pixels arranged along the second direction among the pixels are arranged along the second direction.

According to one or more embodiments, wherein the second power supply bus lines branch from the first power supply bus line are arranged along the second direction in the display area, and extend in the first direction.

According to one or more embodiments, wherein the second power supply bus lines are electrically connected to adjacent common electrodes.

According to one or more embodiments, wherein the common electrode and the second power supply bus lines are electrically connected to each other through a through hole penetrating an organic layer between the common electrode and the second power supply bus lines.

According to one or more embodiments, wherein the plurality of pixels includes a first pixel, a second pixel, and a third pixel arranged along the first direction in each pixel area in which each of the pixels is arranged.

According to one or more embodiments, the display device further including a sub-area protruding in a second direction from one side of the display area and the non-display area, wherein the sub-area includes at least one pad configured to receive a driving voltage, wherein the power supply line is a conductor electrically connected to the pad to transmit the driving voltage.

According to one or more embodiments, wherein the scan driving portion includes a first scan driving portion on a first side of the display area and a second scan driving portion on a second side facing the first side, wherein the first power supply bus line is located between the first scan driving portion and the display area and between the second scan driving portion and the display area.

According to one or more embodiments, wherein the second power supply bus line is located outside the first scan driving portion and the second scan driving portion.

According to one or more embodiments, the display device further including: a write scan line connected to the plurality of pixels from the scan driving portion and configured to output a write scan signal; a control scan line connected to the plurality of pixels from the scan driving portion and configured to output a control scan signal; and an initialization scan line connected to the plurality of pixels from the scan driving portion and configured to output an initialization scan signal.

According to one or more embodiments, wherein the write scan line, the control scan line, and the initialization scan line overlap with the first power supply bus line.

According to one or more embodiments, an electronic device including: a display device; a window on the display device; and a bottom cover below the display device, wherein the display device includes: a substrate including a display area and a non-display area; a plurality of pixels in the display area; a scan driving portion configured to apply scan signals to the plurality of pixels and is located in the non-display area on a first side of the display area; a first power supply bus line in the non-display area and is arranged closer to the display area than the scan driving portion is, the first power supply bus line being around the display area and electrically connected to the pixels; and a second power supply bus line in the non-display area and arranged farther from the display area than the scan driving portion is, the second power supply bus line being around the first power supply bus line, wherein the first power supply bus line and the second power supply bus line are branched from one power supply line and are electrically connected to each other.

According to the display device and the electronic device including the same according to the embodiments, the voltage drop of the driving voltage transmitted to the pixels may be reduced by arranging the second power supply line (the second power supply bus line) close to the common electrode. Accordingly, the power consumption of the display device and the electronic device including the same may be reduced.

In some embodiments, the second power supply line is branched and arranged so that the second power supply line surrounds the scan driving portion, thereby preventing damage to the scan driving portion from static electricity.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

FIG. 1 is a perspective view illustrating a display device according to one or more embodiments.

FIG. 2 is a plan view illustrating a display panel according to one or more embodiments.

FIG. 3 is a block diagram illustrating a display device according to one or more embodiments.

FIG. 4 is an equivalent circuit diagram illustrating a light emitting control signal and a sub-pixel according to one or more embodiments.

FIG. 5 is a plan view illustrating sub-pixels, signal lines, and power supply lines arranged in a display panel according to one or more embodiments.

FIG. 6 is a plan view to illustrate the electrical connection between a first power supply bus line and a common electrode.

FIG. 7 is a plan view illustrating sub-pixels, signal lines, and power supply lines arranged in a display panel according to one or more embodiments.

FIG. 8 is a plan view illustrating the electrical connection between a first power supply bus line and a common electrode.

FIG. 9 is an enlarged plan view of an area A1 of FIG. 2.

FIG. 10 is a cross-sectional view taken along the line I1-I1’ of FIG. 9.

FIG. 11 is a layout diagram illustrating a light emitting element layer of a display panel according to one or more embodiments.

FIG. 12 is a cross-sectional view illustrating an example of a cross-section of a display panel corresponding to the line X1-X1’ of FIG. 11.

FIG. 13 is a cross-sectional view illustrating an area A2 of FIG. 12 in detail.

FIGS. 14 and 15 are example drawings illustrating a smart watch including a display device according to one or more embodiments.

FIG. 16 is an exploded perspective view of a smart watch including a display device according to one or more embodiments.

FIG. 17 is an example drawing illustrating a virtual reality device including a display device according to one or more embodiments.

FIG. 18 is an example drawing illustrating a head-mounted display device including a display device according to one or more embodiments.

FIG. 19 is an example drawing illustrating an automobile instrument panel and center fascia including display devices according to one or more embodiments.

FIG. 20 is an example drawing illustrating a transparent display device including a display device according to one or more embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and/or the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Additionally, the use of cross-hatching and/or shading in the accompanying drawings is generally provided to illustrate boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like of the elements, unless otherwise specified.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

For example, an implanted region illustrated as a rectangle may have rounded or curved features and/or a gradient of an implant concentration at its edges, rather than a binary change from an implanted region to a non-implanted region. Likewise, a buried region formed by implantation may result in some implantation in the region between the buried region and a surface through which the implantation takes place. Thus, the regions illustrated in the drawings are schematic in nature and their shapes are not intended to illustrate the actual shape of a region of a device, and thus, are not intended to be limiting. Additionally, as those having ordinary skill in the art would realize, the described embodiments may be modified in various different ways, all without departing from the spirit and/or scope of the present disclosure.

As used herein, the phrases “on a plane” and “in a plan view” may refer to a view of a target portion from the top, and the phrases “on a cross-section” and “in a cross-sectional view” may refer to a view of a cross-section formed by vertically cutting a target portion from the side.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being "electrically connected" to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” "includes," "including," "has," "have," and "having," when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression "A and/or B" denotes A, B, or A and B. Expressions such as “at least one of,” when preceding a list of elements, modify the entire list of elements and do not modify the individual elements of the list. For example, the expression "at least one of a, b, or c," “at least one of a, b, and c,” and “at least one selected from the group consisting of a, b, and c” indicates only a, only b, only c, both a and b, both a and c, both b and c, all of a, b, and c, or variations thereof.

As used herein, the term "substantially," "about," and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms "use," "using," and "used" may be considered synonymous with the terms "utilize," "utilizing," and "utilized," respectively.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein.

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person having ordinary skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

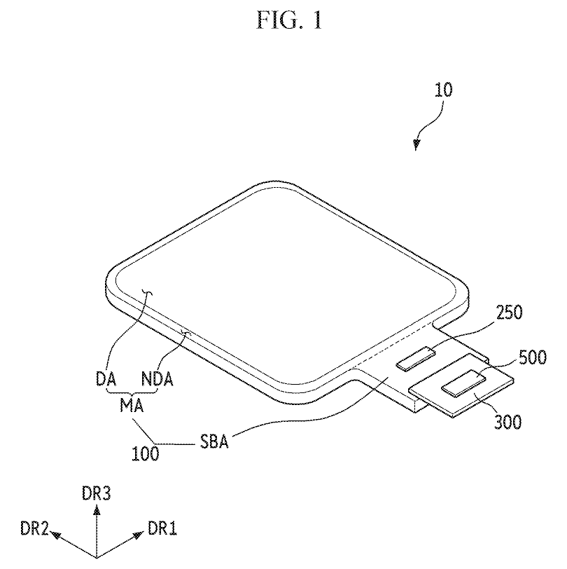

FIG. 1 is a perspective view illustrating a display device according to one or more embodiments.

Referring to FIG. 1, the display device 10 is a device for displaying a video and/or a still image, and may be a mobile phone, a smart phone, a tablet personal computer, or a portable electronic device, such as a smart watch, a watch phone, a mobile communication terminal, an electronic notebook, an e-book, a portable multimedia player (PMP), a navigation system, an ultra mobile PC (UMPC), and/or the like. The display device 10 may also be included in various kinds of electronic devices, such as televisions, laptops, monitors, billboards, Internet of Things (IOT) devices, and/or the like, and may be used as a display screen. Also, the display device 10 may be included in other suitable electronic devices, such as a virtual reality (VR) device or an augmented reality (AR) device, and may be used to display an image in the electronic devices. In one or more embodiment, an electronic device including the display device 10 may further include a display device storage portion in which the display device 10 is stored, and/or a case or a cover for protecting the display device 10.

In one or more embodiments, the display device 10 may be a light emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and/or a miniaturized light-emitting display device utilizing a micro or nano light emitting diode (micro LED or nano LED). Hereinafter, for convenience of illustration, the display device 10 may be described in more detail in the context of a micro-light emitting display device, but the present disclosure is not limited thereto. Further, hereinafter, for convenience of illustration, an ultra-small light emitting diode may be described in more detail as a light emitting element.

The display device 10 includes a display panel 100, a display driving circuit 250, a circuit substrate 300, and a power supply circuit 500.

The display panel 100 may be formed as a rectangular shaped plane having a short side extending in the first direction DR1, and a long side extending in the second direction DR2 that crosses or intersects the first direction DR1. A corner where the short side extending in the first direction DR1 and the long side extending in the second direction DR2 meet each other may be rounded to have a suitable curvature (e.g., a predetermined curvature), or may be formed at a right angle. The planar shape of the display panel 100 is not limited to the rectangle, but may be formed in other suitable polygonal, circular, or oval shapes. The display panel 100 may be formed flat or substantially flat, but is not limited thereto. As an example, the display panel 100 may be formed at left and right ends, and may include curved portions with a constant curvature or a changing curvature. In addition, the display panel 100 may be flexibly formed to be bent, curved, bent, folded, and/or rolled.

The display panel 100 may include a main area MA and a sub-area SBA.

The main area MA may include a display area DA that displays an image, and a non-display area NDA that may be a surrounding area (e.g., around a periphery) of the display area DA. The display area DA may include a plurality of pixels that display an image. Each pixel may include a plurality of sub-pixels. For example, each of the pixels may include a first sub-pixel that emits light of a first color (e.g., a first light), a second sub-pixel that emits light of a second color (e.g., a second light), and a third sub-pixel that emits light of a third color (e.g., a third light), but the present disclosure is not limited thereto.

The sub-area SBA may protrude from one side of the main area MA in a second direction DR2 (e.g., in the longitudinal direction of the display panel 100). In FIG. 1, the sub-area SBA is illustrated as being unfolded, but the sub-area SBA may be bent, in which case it may be arranged on a bottom surface of the display panel 100. When the sub-area SBA is bent, it may overlap with the main area MA in a third direction DR3, which is the thickness direction of the display panel 100. The display driving circuit 250 may be arranged in the sub-area SBA.

The display driving circuit 250 may generate signals and voltages for driving the display panel 100. The display driving circuit 250 may be formed as an integrated circuit (IC), and may be attached to the display panel 100 using a chip on glass (COG) method, a chip on plastic (COP) method, or an ultrasonic bonding method, but the present disclosure is not limited thereto. In one or more embodiments, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as a flexible printed circuit substrate, a printed circuit substrate, or a chip on film.

The power supply circuit 500 may generate a plurality of panel driving voltages according to an external power supply voltage. The power supply circuit 500 may be formed as an integrated circuit (IC), and may be attached to the circuit substrate 300 using a COF method.

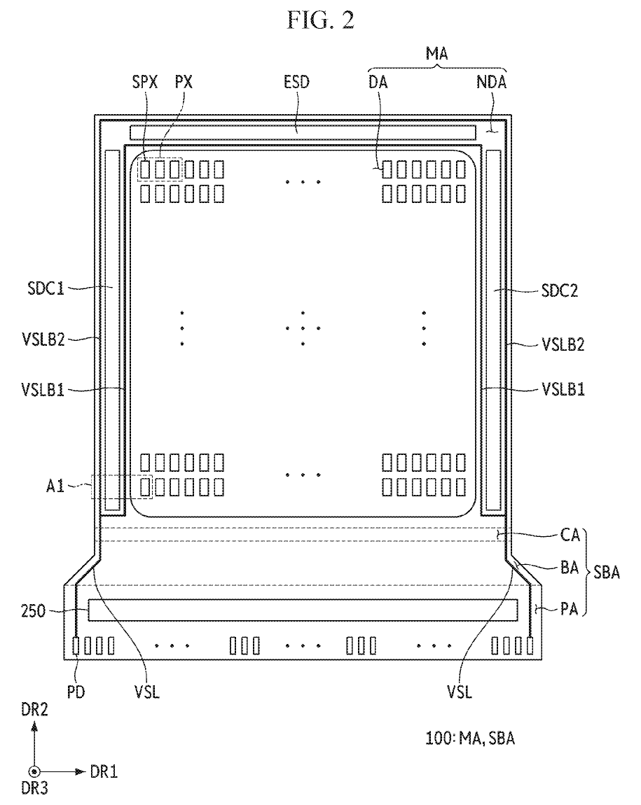

FIG. 2 is a plan view illustrating a display panel according to an embodiment. FIG. 2 illustrates that the sub-area SBA is unfolded without being bent.

Referring to FIGS. 1 and 2, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed in the center of the main area MA.

The display area DA includes pixels PX for displaying an image, and each pixel PX may include a plurality of sub-pixels SPX. A pixel PX may be defined as a sub-pixel group that is the smallest unit capable of expressing a white gradation (e.g., a white grayscale level or value).

The non-display area NDA may be arranged to be adjacent to the display area DA. The non-display area NDA may be an area outside the display area DA. The non-display area NDA may be arranged to surround (e.g., around a periphery of) the display area DA. The non-display area NDA may be an edge area of the display panel 100.

A first scan-driving portion SDC1 and a second scan-driving portion SDC2 may be located in the non-display area NDA. The first scan-driving portion SDC1 is located on one side (e.g., the left side) of the display panel 100, and the second scan-driving portion SDC2 is located on the other side (e.g., the right side) of the display panel 100 but are not limited thereto.

Each of the first scan-driving portion SDC1 and the second scan-driving portion SDC2 may be electrically connected to the display-driving circuit 250 through scan fan out lines. Each of the first scan-driving portion SDC1 and the second scan-driving portion SDC2 may receive a scan control signal from the display-driving circuit 250, generate scan signals according to the scan control signal, and output them to scan lines.

The electrostatic discharge protection circuit ESD may be placed in the non-display area NDA. The electrostatic discharge protection circuit ESD may be placed on one side (e.g., the top side) of the display panel 100, but the present disclosure is not limited thereto. For example, the electrostatic discharge protection circuit ESD may be placed on the bottom side of the display panel 100 or may be omitted.

The sub-area SBA may protrude from one side of the main area MA in the second direction DR2. The length of the sub-area SBA in the second direction DR2 may be smaller than the length of the main area MA in the second direction DR2. The length of the sub area SBA in the first direction DR1 may be less than the length of the main area MA in the first direction DR1, or may be equal to or substantially equal to the length of the main area MA in the first direction DR1. In some embodiments, as shown in FIG. 2, the length of the sub area SBA in the first direction DR1 may be greater than the length of the main area MA in the first direction DR1. The sub-area SBA may be bent or curved and arranged below the main area MA. In this case, the sub-area SBA may overlap with the main area MA in the third direction DR3.

The sub-area SBA may include a connection area CA, a pad area PA, and a bending area BA.

The connection area CA may be an area protruding from one side of the main area MA in the second direction DR2. One side of the connection area CA may be in contact with the non-display area NDA of the main area MA, and another side of the connection area CA may be in contact with the bending area BA.

The pad area PA is an area where pads PD and the display driving circuit 250 are arranged. The display driving circuit 250 may be attached to driving pads of the pad area PA using a conductive adhesive member, such as an anisotropic conductive film. The circuit substrate 300 may be attached to the pads PD of the pad area PA using a conductive adhesive member, such as an anisotropic conductive film. One side of the pad area PA may be in contact with the bending area BA.

The bending area BA is an area that may be bent (e.g., a bent area). When the bending area BA is bent, the pad area PA may be arranged below (e.g., underneath) the connection area CA and below (e.g., underneath) the main area MA. The bending area BA may be arranged between the connection area CA and the pad area PA. One side of the bending area BA may be in contact with the connection area CA, and another side of the bending area BA may be in contact with the pad area PA.

The power supply line VSL may be placed in the non-display area NDA. The power supply line VSL extends from the pad PD toward the display area. The power supply line VSL may be electrically connected to at least one pad PD located in the pad area PA. For example, the power supply line VSL may be electrically connected to a plurality of pads PD positioned at both ends of the pad area PA. At least one pad PD electrically connected to the power supply line VSL may be a power pad to which a second power voltage VSS is applied. The connection structure between the power supply line VSL and the pad PD is not limited to the above-described embodiments and may vary depending on the specific implementation. The power supply line VSL may be a conductor delivering a low-potential power supply (the second power supply voltage VSS) to the light-emitting device described later.

The power supply line VSL may be branched into a first power bus line VSLB1 and a second power bus line VSLB2.

The first power bus line VSLB1 and the second power bus line VSLB2 may be disposed to be around (e.g., to surround) the display area DA in the non-display area NDA. For example, the first power bus line VSLB1 may be disposed on the left/right sides and the top side of the display area DA so as to be around (e.g., to surround) three sides of the display area DA. The first power bus line VSLB1 may be disposed close to the common electrode so as to reduce a voltage drop of a drive voltage supplied to the pixels PX.

The second power bus line VSLB2 may be disposed more outward than the first power bus line VSLB1 so as to be around (e.g., to surround) the first power bus line VSLB1. The second power bus line VSLB2 may be disposed more outward than the first scan driver SDC1, the second scan driver SDC2, and the electrostatic discharge protection circuit ESD. For example, the second power bus line VSLB2 may be disposed further to the left than the first scan driver SDC1, further to the right than the second scan driver SDC2, and further to the top than the electrostatic discharge protection circuit ESD so as to surround the first power bus line VSLB1. Therefore, the first scan driver SDC1 and the second scan driver SDC2 may be surrounded by the first power bus line VSLB1 and the second power bus line VSLB2. Thus, by being surrounded by the first power bus line VSLB1 and the second power bus line VSLB2, the first scan driver SDC1 and the second scan driver SDC2 may be protected from damage due to electrostatic discharge. Furthermore, the electrostatic discharge protection circuit ESD may be surrounded by the first power bus line VSLB1 and the second power bus line VSLB2.

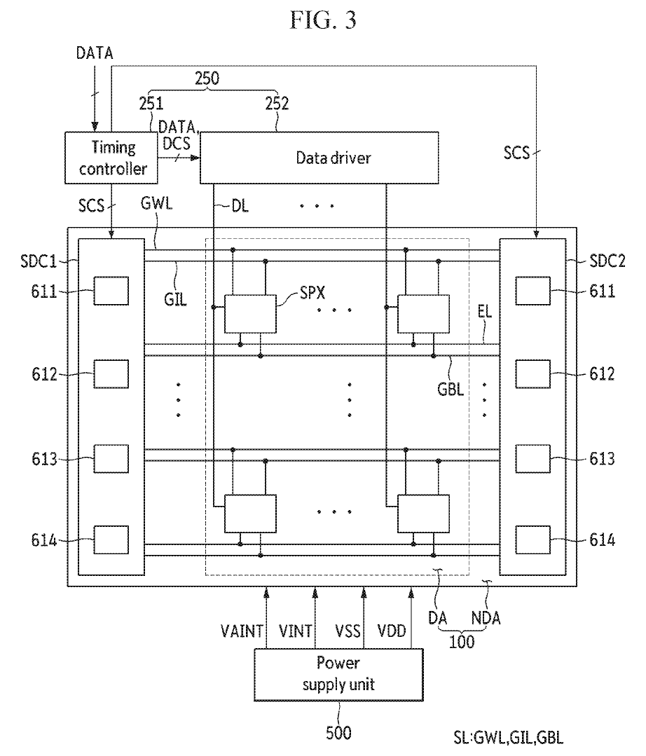

FIG. 3 is a block drawing illustrating a display device according to one or more embodiments.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form along the first direction DR1 and the second direction DR2. For example, the plurality of pixels PX may be arranged along the rows and columns of a matrix along the first direction DR1 and the second direction DR2. The plurality of scan lines SL and the plurality of emission control lines EL may extend in the first direction DR1 and may be disposed along the second direction DR2. The plurality of data lines DL may extend in the second direction DR2 and may be disposed along the first direction DR1. The plurality of scan lines SL may include a plurality of write scan lines GWL, a plurality of initialization scan lines GIL, and a plurality of bias scan lines GBL.

Each of the plurality of sub-pixels SPX may be connected to a write scan line GWL from among the plurality of write scan lines GWL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light from the light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 includes a timing control circuit (e.g., a timing controller) 251 and a data driving circuit (e.g., a data driver) 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 251 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit (e.g., a power supply unit) 500 may generate a plurality of panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

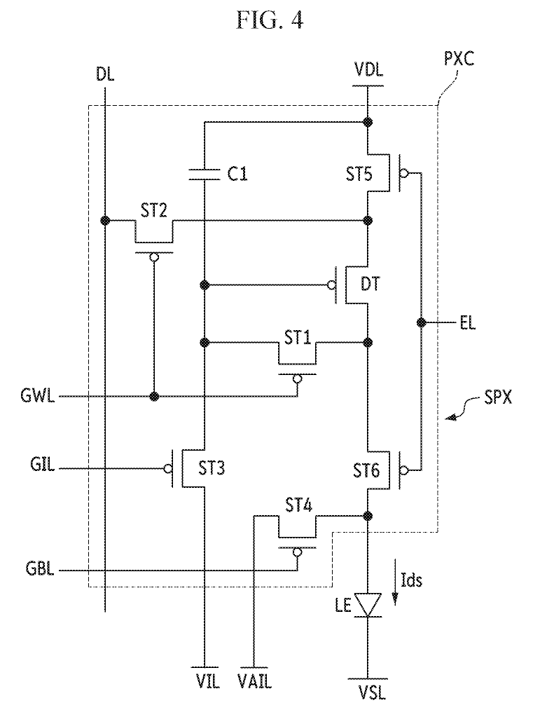

FIG. 4 is an equivalent circuit drawing illustrating a sub-pixel according to one or more embodiments.

Referring to FIG. 4 in addition to FIGS. 1 – 3, each sub-pixel SPX may include a pixel circuit PXC and a light-emitting element LE that is electrically connected to the pixel circuit PXC.

A sub-pixel SPX according to one or more embodiments may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The pixel circuit PXC may control a drive current (Ids) supplied to the light-emitting element LE in response to drive signals supplied to the sub-pixel SPX (e.g., a write scan signal, an initialization scan signal, a control scan signal, a bias scan signal, a light-emission control signal, and a data voltage). The pixel circuit PXC may control emission timing and luminance of the light-emitting element LE.

The pixel circuit PXC includes a driving transistor DT, switching elements, and a capacitor C1. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as "driving current") flowing between the first electrode and the second electrode of the driving transistor DT according to a data voltage applied to a gate electrode of the driving transistor DT.

The light emitting element LE1 may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage VSS is applied.

A capacitor C1 is formed between a gate electrode of a driving transistor DT and a first power supply line VDL to which a first power supply voltage VDD is applied. The first power supply voltage VDD may be a voltage of a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, the gate electrode of the fourth transistor ST4 may be connected to the bias scan line GBL, and the gate electrodes of the fifth and sixth transistors ST5 and ST6 may be connected to the emission control line EL. Because the first to sixth transistors ST1, ST2, ST3, ST4, ST5, and ST6 are formed as p-type MOSFET and they may be turned on when a scan signal of a gate low voltage and an emission control signal of a gate low voltage are applied to the initialization scan line GIL, the write scan line GWL, the bias scan line GBL, and the emission line EL, respectively. The one electrode of the third transistor ST3 and the one electrode of the fourth transistor ST4 may be connected to the initialization voltage lines VIL, VAIL.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor.

Furthermore, because the first transistor ST1 and the third transistor ST3 are formed as n-type MOSFET, the first transistor ST1 may be turned on when a write scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission control signal of a gate low voltage are applied.

Alternatively, the fourth transistor ST4 may be formed as an n-type MOSFET, such that each active layer of the fourth transistor may be formed as an oxide semiconductor. When the fourth transistor is formed as an n-type MOSFET, it may turn on when a gate high voltage scan signal is applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and an emission control signal of a gate high voltage are applied.

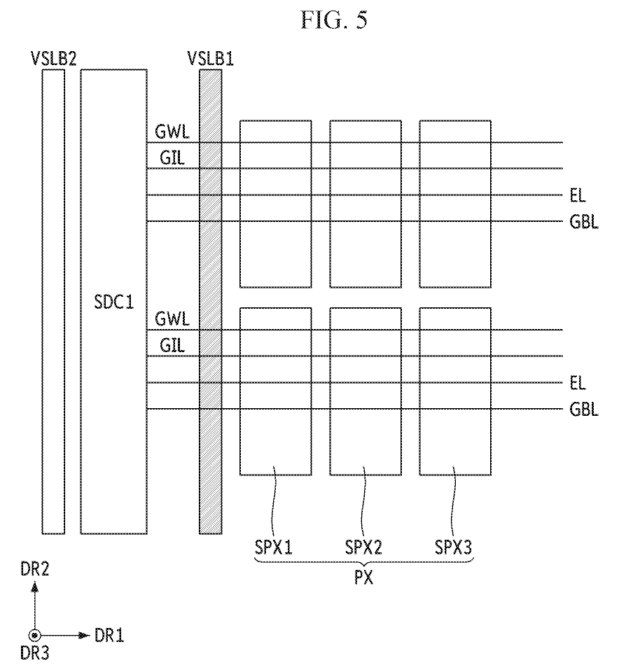

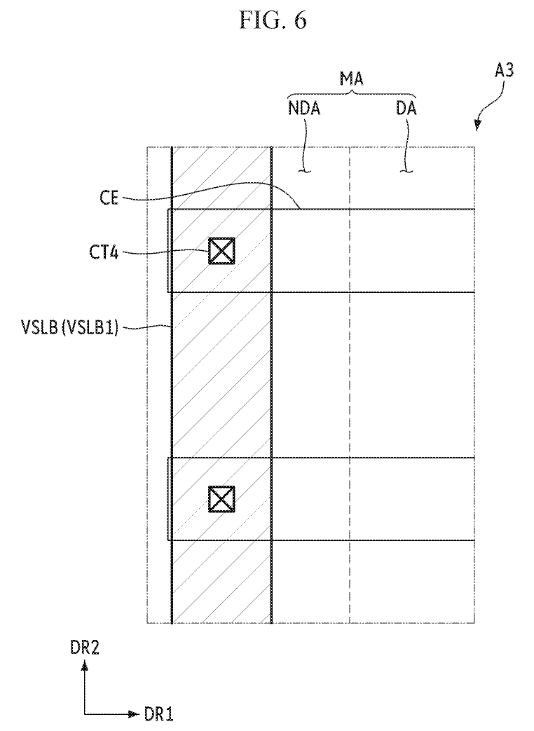

FIG. 5 is a plan view illustrating sub-pixels, signal lines, and power supply lines arranged in a display panel according to one or more embodiments. FIG. 6 is a plan view to illustrate the electrical connection between a first power supply bus line and a common electrode.

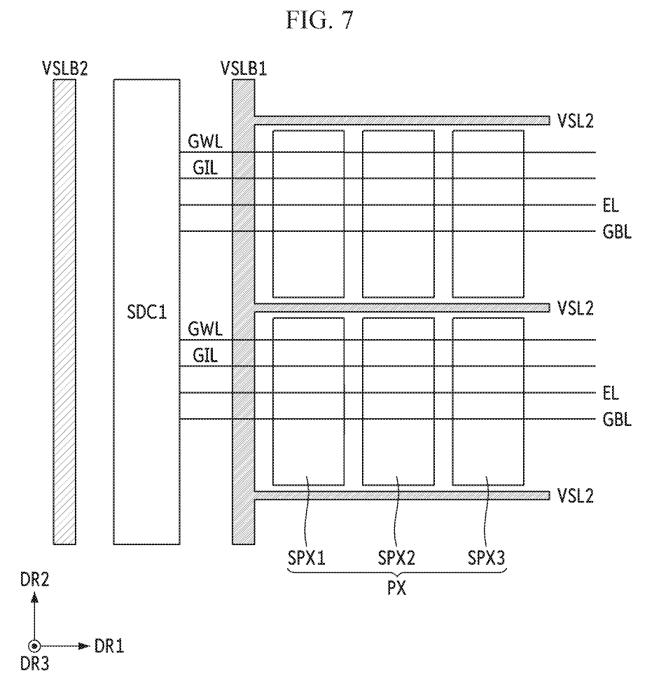

For example, FIG. 5 illustrates an approximate arrangement of a first power supply bus line VSLB1, a first scan driving portion SDC1, and a second power supply bus line VSLB2 in a portion of a display area DA including two pixel areas PXA in which two pixels PX are arranged along a second direction DR2 in a portion of pixels PX arranged on a display panel 100 and a non-display area NDA. Also, it (e.g., FIG. 5) illustrates an approximate arrangement of signal lines (GWL, GIL, GBL, EL) extending from the first scan driving portion SDC1 to the pixels PX. In one or more embodiments, second power supply branch lines VSL2 may be branched from the first power supply bus line VSLB1, as shown in FIG. 7.

The first power supply bus line VSLB1 and the second power supply bus line VSLB2 extend in the second direction DR2. As shown in FIG. 6, a plurality of common electrodes CE are arranged along the second direction DR2 and each extends in the first direction DR1. The common electrode CE may partially overlap with the first power supply bus line VSLB1. For example, referring to FIG. 6, the common electrode CE may overlap with the first power supply bus line VSLB1 at one end and may be electrically connected to the first power supply bus line VSLB1 through a pixel connection hole CT4 at the overlapping portion.

The first power supply bus line VSLB1 and the second power supply bus line VSLB2 are connected to the second power supply line VSL described with reference to FIG. 4. The first power supply bus line VSLB1 and the second power supply bus line VSLB2 may be electrically connected to each other to form a single power supply line. In one example, the first power supply bus line VSLB1 and the second power supply bus line VSLB2 may be branches from the second power supply line (VSL of FIG. 2) and may be different portions of the second power supply line (VSL of FIG. 2). For example, the first power supply bus line VSLB1 and the second power supply bus line VSLB2 may be different portions of the second power supply line (VSL of FIG. 2).

The second power supply lines VSL may be electrically connected to a common electrode arranged on a backplane layer inside and/or outside the display area DA. The common electrode CE may be arranged at least in the display area DA. For example, the common electrode CE may be arranged in the display area DA and may also be arranged in a portion of a non-display area NDA located around the display area DA. The common electrode CE may be electrically connected to the light emitting elements LE in the display area DA and may be electrically connected to the second power supply lines VSL inside the display area DA and/or in the non-display area NDA.

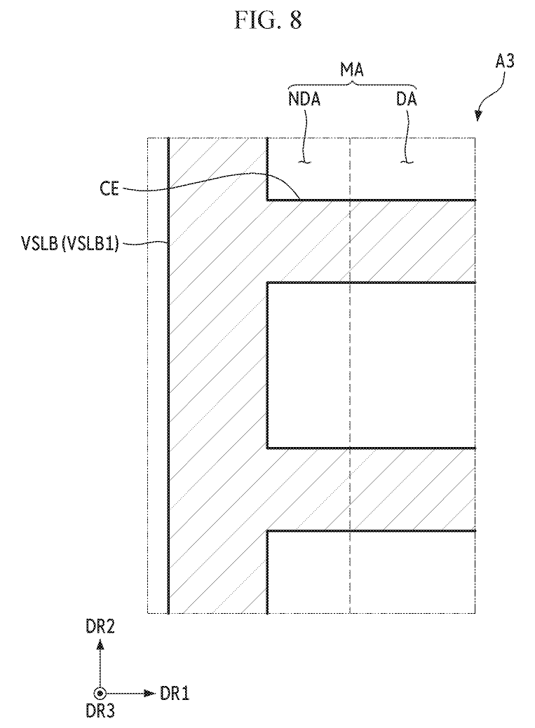

FIG. 7 is a plan view illustrating sub-pixels, signal lines, and power supply lines arranged in a display panel according to one or more embodiments. FIG. 8 is a plan view to illustrate the electrical connection between a first power supply bus line and a common electrode.

FIGS. 7 and 8 differ from FIGS. 5 and 6 in that they include second power branch lines VSL2 branched from the first power supply bus line VSLB1. In the embodiments of FIGS. 7 and 8, descriptions that overlap with those of the embodiments of FIGS. 5 and 6 are omitted.

Referring to FIGS. 7 and 8, the first power supply bus line VSLB1 and the second power supply bus line VSLB2 extend in the second direction DR2, while the second power supply branch lines VSL2 branched from the first power supply bus line VSLB1 may extend in the first direction DR1. In one or more embodiments, a plurality of second power supply branch lines VSL2 may be arranged along the first direction DR1 between two adjacent pixel columns in the display area DA.

In one or more embodiments, the second power supply branch lines VSL2 may not cross with other signal lines at least in the display area DA.

In describing the embodiments, the second power supply branch lines VSL2 spaced (e.g., spaced apart) from each other in the display area DA are referred to as multiple, but the second power supply branch lines VSL2 may be electrically connected to each other to form a single power supply line. For example, the second power supply branch lines VSL2 shown in FIG. 7 may be portions branched from a single power supply line and may be different portions of the single power supply line.

In one or more embodiments, the second power supply branch line VSL2 and the common electrode CE may overlap. The common electrode CE may be electrically connected to the second power supply branch line VSL2 through the pixel connection hole CT4 at the overlapping portion.

In the embodiments of FIGS. 5 – 8, the signal lines and the second power supply lines VSL are illustrated as extending in a straight line shape along the first direction DR1 or the second direction DR2, but the present disclosure is not limited thereto. For example, FIG. 5 and FIG. 7 illustrate the overall shape, position, extension direction, arrangement direction, etc. of each of the signal lines (GWL, GIL, GBL, EL) and the power supply lines VSL (e.g., VSL2), VSLB1, and VSLB2, and the shape, position, arrangement direction, and/or size, etc. of each of the signal lines and the power supply lines PL may be adjusted or changed in consideration of circuit density, minimization of interference between circuits, defect avoidance, and/or the arrangement shape of the sub-pixels SPX. For example, each of the signal lines and the power supply lines VSL, VSLB1, and VSLB2 may extend entirely or substantially along the first direction DR1 or the second direction DR2, but at least some of the signal lines and the power supply lines VSL, VSLB1, and VSLB2 may have a shape such as being bent and/or folded partially.

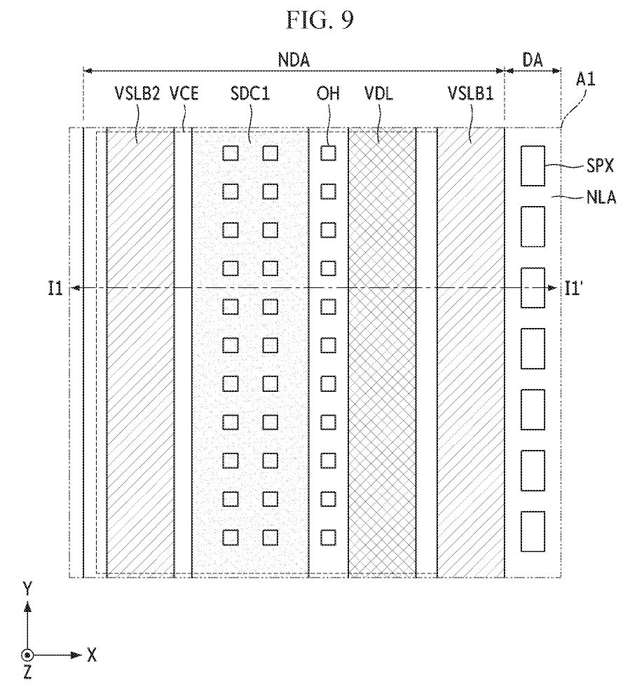

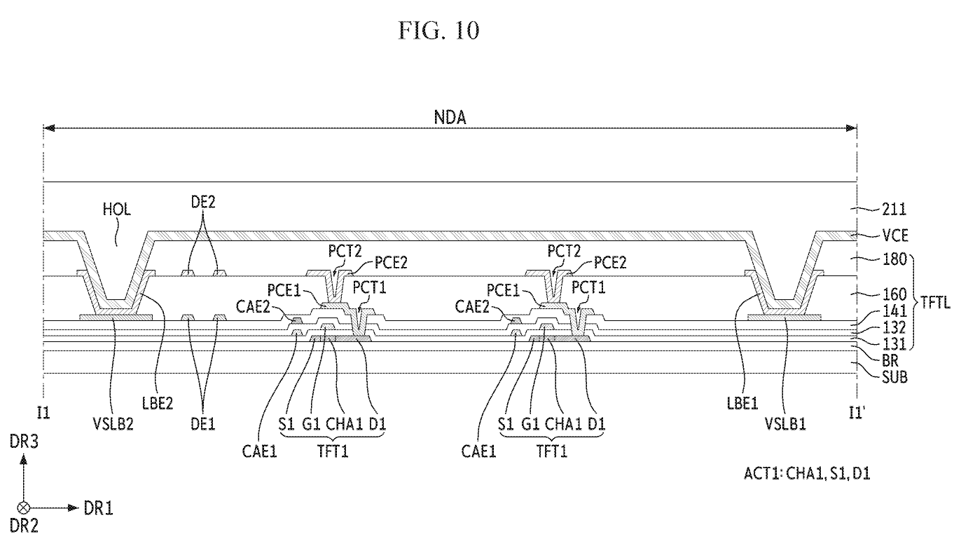

FIG. 9 is an enlarged plan view of an area A1 of FIG. 2. FIG. 10 is a cross-sectional view taken along line I1-I1’ of FIG. 9.

Referring to FIG. 9, a display device 10 according to one or more embodiments may include sub-pixels SPX in a portion overlapping a display area DA and may include a first power supply bus line VSLB1, a first power supply line VDL, a scan driving portion SDC1, a plurality of hole patterns OH, a power supply connection electrode VCE, and a second power supply bus line VSLB2 in a portion overlapping a non-display area NDA.

The first power supply bus line VSLB1, the first power supply line VDL, the scan driving portion SDC1, and the second power supply bus line VSLB2 may be arranged in order to be away from the display area DA.

Referring to FIGS. 9 and 10, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film for protecting the first thin-film transistors TFT1 of the thin-film transistor layer TFTL from moisture penetrating through the substrate SUB which is vulnerable to moisture permeation. The barrier film BR may be formed of a plurality of inorganic films that are alternately stacked.

A first thin-film transistor TFT1 may be arranged on the barrier film BR.

The first thin-film transistor TFT1 may include a first active layer ACT1 and a first gate electrode G1.

The first active layer ACT1 of the first thin-film transistor TFT1 may be arranged on the barrier film BR. The first active layer ACT1 of the first thin-film transistor TFT1 may include polycrystalline silicon, monocrystalline silicon, low-temperature polycrystalline silicon, or amorphous silicon. Alternatively, the first active layer ACT1 of the first thin-film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be arranged on the first channel area CHA1, the first source area S1, and the first drain area D1 of the thin-film transistor TFT1 and on the barrier film BR.

A first gate metal layer may be arranged on the first gate insulating film 131. The first gate metal layer may include a first gate electrode G1 of a thin-film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged spaced (e.g., spaced apart) from each other in FIG. 10, the first gate electrode G1 and the first capacitor electrode CAE1 may be connected to each other.

A second gate insulating film 132 may be arranged on the first gate electrode G1 of the first thin-film transistor TFT1, the first capacitor electrode CAE1, and the first gate insulating film 131.

A second gate metal layer may be arranged on the second gate insulating film 132. The second gate metal layer may include a second capacitor electrode CAE2. The second capacitor electrode CAE2 may overlap the first capacitor electrode CAE1 of the capacitor C1 in the third direction DR3. Because the second gate insulating film 132 has a suitable dielectric constant (e.g., a predetermined dielectric constant), the capacitor (e.g., the capacitor C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2 and on the second gate insulating film 132.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first driving electrode DE1 is arranged on (e.g., at) the same layer as the first source connection electrode PCE1 and may serve as a connection electrode in a circuit that drives the first scan driving portion SDC1.

A first planarization organic film 160 may be arranged on the first source connection electrode PCE1 to planarize a step caused by the first thin-film transistor TFT1.

A second data metal layer may be arranged on the first planarization organic film 160. The second data metal layer may include a second source connection electrode PCE2 and a plurality of second driving electrodes DE2. The second source connection electrode PCE2 may be connected to the first source connection electrode PCE1 through a second pixel contact hole PCT2 penetrating the first planarization organic film 160. The plurality of second driving electrodes DE2 may be arranged on (e.g., at) the same layer as the second source connection electrode PCE2 and may serve as connection electrodes in a circuit that drives the first scan driving portion SDC1.

A second planarizing organic film 180 may be arranged on a second source connection electrode PCE2.

In one or more embodiments, the first power supply bus line VSLB1 may be arranged inside the first transistor TFT1 (e.g., in the thin film transistor layer TFTL) in a portion overlapping the non-display area NDA. That is, the first power supply bus line VSLB1 may be arranged closer to the display area DA than the first transistor TFT1. The first power supply bus line VSLB1 may be arranged on the first interlayer insulating film 141, and a portion of the top surface may be exposed through a hole penetrating the first planarization organic film 160 and the second planarization organic film 180. The exposed top surface of the first power supply bus line VSLB1 may be in contact with the first line connection electrode LBE1.

The first line connection electrode LBE1 may be arranged on a portion overlapping the non-display area NDA and may be arranged on the first power supply bus line VSLB1. In one or more embodiments, the first line connection electrode LBE1 may be arranged to extend to be around (e.g., to surround) the display area DA in a similar shape to the first power supply bus line VSLB1 on a plane.

The first line connection electrode LBE1 may be arranged on the first planarization organic film 160 and may be in direct contact with the first power supply bus line VSLB1 through a hole penetrating the first planarization organic film 160. The first line connection electrode LBE1 may be arranged between the first power supply bus line VSLB1 and a pixel electrode layer (e.g., a common electrode or the power supply connection electrode VCE) described below and may serve as a bridge to electrically connect them to each other. Accordingly, the second driving voltage VSS applied through the first power supply bus line VSLB1 may be transmitted to the common electrode CE or to the power supply connection electrode VCE through the first line connection electrode LBE1. The first line connection electrode LBE1 and the common electrode CE may be in direct contact with each other but may also be connected through a separate connection electrode. In one or more embodiments, as shown in FIG. 10, the first line connection electrode LBE1 and the power supply connection electrode VCE may be in direct contact with each other but may also be connected through a separate connection electrode.

In one or more embodiments, the first power supply line VDL1 (e.g., VDL) may be arranged between the first transistor TFT1 and the first power supply bus line VSLB1 in a portion overlapping the non-display area NDA. The first power bus line VSLB1 may be arranged on the first planarization organic film 160.

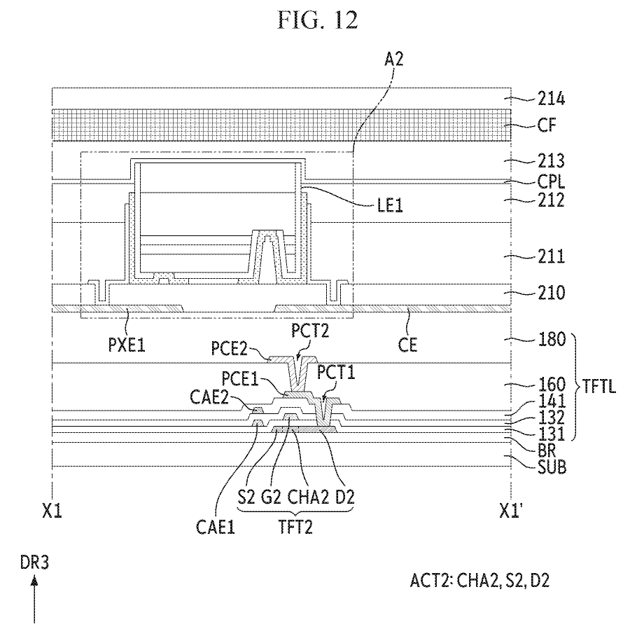

The first scan driving portion SDC1 may be arranged in a portion overlapping the non-display area NDA and may be arranged between the first power supply bus line VSLB1 and the second power supply bus line VSLB2. The first scan driving portion SDC1 may include a plurality of second thin-film transistors TFT2 (e.g., see FIG. 12) and a plurality of driving electrodes DE1 and DE2. For example, in FIG. 7, two first thin-film transistors TFT1 and two driving electrodes DE1 and DE2 are illustrated, but the number of the first thin-film transistors TFT1, the second thin-film transistors TFT2, and two driving electrodes DE1 and DE2 is not limited thereto.

As shown in FIG. 12, the second thin-film transistor TFT2 may be arranged on the barrier film BR and may constitute a driving circuit of the scan driving portion SDC1.

For example, as shown in FIG. 9, the plurality of hole patterns OH may be arranged between the first power supply bus line VSLB1 and the second power supply bus line VSLB2, and some of the plurality of hole patterns OH may overlap with the first scan driving portion SDC1. The display device 10 may include an organic film such as a first planarization organic film 160 and a second planarization organic film 180, and gas may be generated during the manufacturing process of the display device 10. If the gas generated in the organic films such as the first planarization organic film 160 and the second planarization organic film 180 is not smoothly discharged, the phenomenon of lifting of the first planarization organic film 160 and the second planarization organic film 180 by the gas may occur. Accordingly, the conductive layers arranged on the underside of the first planarization organic film 160 and the second planarization organic film 180, such as the electrodes of the first thin-film transistor TFT1 arranged in the display area DA (or in the non-display area NDA), and the driving electrodes DE1 and DE2 arranged in the non-display area NDA, may be damaged.

The power supply connection electrode VCE of the display device 10 may be widely arranged in the non-display area NDA to partially overlap the first power supply bus line VSLB1 and the second power supply bus line VSLB2. Furthermore, because the power supply connection electrode VCE is arranged to cover the scan driving portions SDC1 and SDC2, the area between the scan driving portions SDC1 and SDC2 and the first power supply bus line VSLB1 and between the scan driving portions SDC1 and SDC2 and the second power supply bus line VSLB2 may also be covered by the power supply connection electrode VCE. Therefore, if an exhaust path for gas generated from the first planarization organic film 160 and the second planarization organic film 180 is not formed, the display device 10 according to one or more embodiments may be vulnerable to the lifting phenomenon. The display device 10 according to one or more embodiments may include a plurality of hole patterns OH penetrating the power supply connection electrode VCE arranged in the non-display area NDA. The hole patterns OH may form an exhaust path for gas generated from the first planarization organic film 160 and the second planarization organic film 180 during the manufacturing process of the display device 10.

The second power supply bus line VSLB2 may be arranged outside the first transistor TFT1 in a portion overlapping the non-display area NDA. That is, the second power supply bus line VSLB2 may be arranged farther from the display area DA than the first transistor TFT1. The second power supply bus line VSLB2 may be arranged on the first interlayer insulating film 141, and a portion of the top surface may be exposed through a hole penetrating the first planarization organic film 160 and the second planarization organic film 180. The exposed top surface of the second power supply bus line VSLB2 may be in contact with the second line connection electrode LBE2.

The second line connection electrode LBE2 may be arranged on a portion overlapping the non-display area NDA and may be arranged on the second power supply bus line VSLB2. In one or more embodiments, the second line connection electrode LBE2 may be arranged to extend to be around (e.g., to surround) the display area DA in a similar shape to the second power supply bus line VSLB2 on a plane.

The second line connection electrode LBE2 may be arranged on the first planarization organic film 160 and may be in direct contact with the second power supply bus line VSLB2 through a hole penetrating the first planarization organic film 160. The second line connection electrode LBE2 may be arranged between the second power supply bus line VSLB2 and the power supply connection electrode VCE to serve as a bridge that electrically connects them to each other.

The first line connection electrode LBE1 and the second line connection electrode LBE2 may be further included in the second data metal layer. Therefore, the first line connection electrode LBE1 and the second line connection electrode LBE2 may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The power supply connection electrode VCE is arranged in a portion overlapping the non-display area NDA and may overlap the second power supply bus line VSLB2, the first scan driving portion SDC1, and the first power supply line VDL. As shown in FIG. 9, the power supply connection electrode VCE may completely cover the second power supply bus line VSLB2, the first scan driving portion SDC1, and the first power supply line VDL on a plane.

The power supply connection electrode VCE may electrically connect the second power supply bus line VSLB2 and the first power supply bus line VSLB1.

The power supply connection electrode VCE may be arranged on the second planarization organic film 180 and may be arranged in the same layer as the common electrode CE of the display area DA. The power supply connection electrode VCE may be made of a transparent conductive material such as indium tin oxide (ITO) and/or indium zinc oxide (IZO) (e.g., transparent conductive oxide (TCO)).

The power supply connection electrode VCE may be in direct contact with the second line connection electrode LBE2 at a portion overlapping a hole HOL penetrating the second planarization organic film 180. The second line connection electrode LBE2 may be arranged between the power supply connection electrode VCE and the second power supply bus line VSLB2 and may serve as a bridge to electrically connect them to each other. That is, the power supply connection electrode VCE may be electrically connected to the second power supply bus line VSLB2 (e.g., via second line connection electrode LBE2).

The barrier film BR, the first gate insulating film 131, the second gate insulating film 132, and the interlayer insulating film 141 may be formed of an inorganic film, such as silicon nitride (SiNₓ), silicon oxide (SiON), silicon oxide (SiOₓ), titanium oxide (TiOₓ), and/or aluminum oxide (AlOₓ).

The first gate metal layer, the second gate metal layer, the first data metal layer, and the second data metal layer may be formed as a single layer or multiple layers of molybdenum (Mo), aluminum (Al), chromium (Cr), gold (Au), titanium (Ti), nickel (Ni), neodymium (Nd), and/or copper (Cu), and/or an alloy thereof.

The first planarization organic film 160 and the second planarization organic film 180 may be formed from an organic film such as an acrylic resin, an epoxy resin, a phenolic resin, a polyamide resin, a polyimide resin, and/or the like.

A second organic layer 211 may be arranged on the second planarization organic film 180 and the power supply connection electrode VCE.

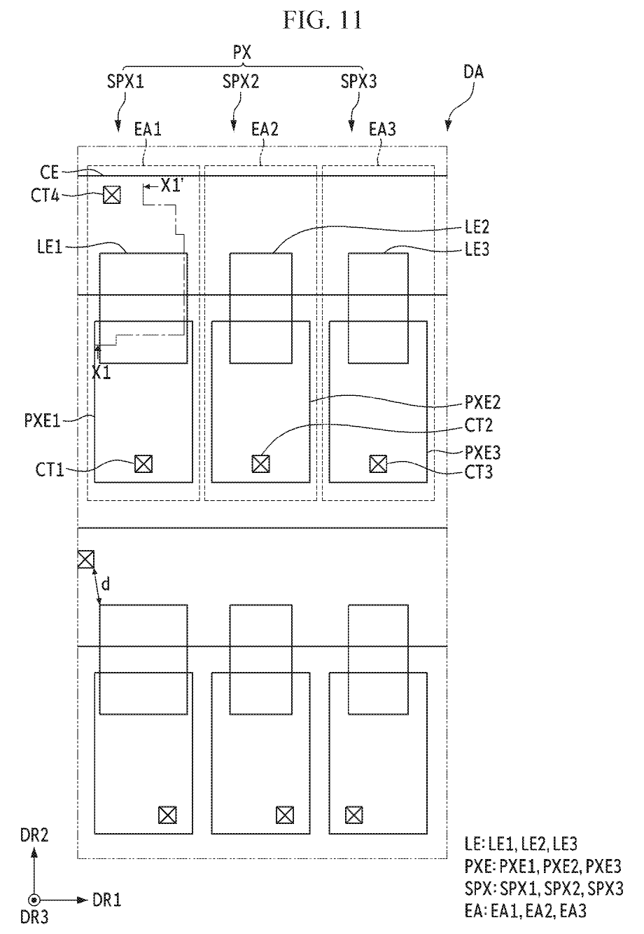

FIG. 11 is a layout diagram illustrating a light emitting element layer of a display panel according to one or more embodiments. For example, FIG. 11 illustrates light emitting elements LE, pixel electrodes PXE, and common electrodes CE included in sub-pixels SPX of each pixel PX in a portion of a display area DA in which two adjacent pixels PX are arranged along a second direction DR2.

Referring to FIG. 11 in addition to FIGS. 3 and 4, pixel electrodes PXE and common electrodes CE of each of the pixels PX may be arranged in the display area DA.

Each of the pixels PX may include a plurality of pixel electrodes PXE and a common electrode CE. For example, each of the pixels PX may include a first pixel electrode PXE1, a second pixel electrode PXE2, a third pixel electrode PXE3, and a common electrode CE. Each of the pixels PX may further include a plurality of light emitting elements LE electrically connected between the plurality of pixel electrodes PXE and the common electrode CE. A detailed description of the detailed structure of each pixel PX will be described later.

The first pixel electrode PXE1 may be the pixel electrode PXE of the first sub-pixel SPX1. The second pixel electrode PXE2 may be the pixel electrode PXE of the second sub-pixel SPX2. The third pixel electrode PXE3 may be the pixel electrode PXE of the third sub-pixel SPX3.

The common electrodes CE may be arranged around the first pixel electrode PXE1, the second pixel electrode PXE2, and the third pixel electrode PXE3 and may be spaced (e.g., spaced apart) from the first pixel electrode PXE1, the second pixel electrode PXE2, and the third pixel electrode PXE3. In one or more embodiments, the common electrode CE may be arranged on (or at) the same layer as the pixel electrodes PXE. For example, the common electrode CE, the first pixel electrode PXE1, the second pixel electrode PXE2, and the third pixel electrode PXE3 may be arranged on (e.g., at) the same layer.

In one or more embodiments, the common electrode CE may extend in one direction, and the first sub-pixel SPX1, the second sub-pixel SPX2, and the third sub-pixel SPX3 of each pixel PX may share one common electrode CE. For example, the common electrode CE may extend in the first direction DR1 in the display area DA, and the pixels PX of each horizontal line arranged along the first direction DR1 from among the pixels PX arranged in the display area DA may share one common electrode CE extending in the first direction DR1. For example, the pixels PX of each horizontal line may include different portions of the common electrode CE arranged in the corresponding horizontal line.

In one or more embodiments, a plurality of common electrodes CE arranged along the second direction DR2 may be arranged in the display area DA. For example, the common electrodes CE may be arranged along the second direction DR2 in the display area DA, and each may extend in the first direction DR1. In one or more embodiments, one common electrode CE is arranged for each horizontal line of the display area DA, and the common electrodes CE of the pixels PX arranged along the second direction DR2 from among the pixels PX arranged in the display area DA (e.g., the pixels PX arranged in different horizontal lines in the display area DA) may be arranged along the second direction DR2.

In one or more embodiments, the common electrode CE of each pixel PX may face the first pixel electrode PXE1, the second pixel electrode PXE2, and the third pixel electrode PXE3 of the corresponding pixel PX. For example, in each pixel PX, the first pixel electrode PXE1, the second pixel electrode PXE2, and the third pixel electrode PXE3 may be sequentially arranged along the first direction DR1, and the common electrode CE may face the first pixel electrode PXE1, the second pixel electrode PXE2, and the third pixel electrode PXE3 in the second direction DR2.

Each of the sub-pixels SPX may include a pixel electrode PXE and a light emitting element LE arranged in the light emitting area EA. In one or more embodiments, when the light emitting element LE is a micro LED of a flip-chip type or a lateral type, each of the sub-pixels SPX may further include a common electrode CE arranged on one surface (e.g., a bottom surface or an top surface) of the light emitting element LE together with the pixel electrode PXE.

In FIG. 11, the sizes of the light emitting areas EA of the sub-pixels SPX are illustrated as being the same, but the present disclosure is not limited thereto. For example, the sizes of the light emitting areas EA of the sub-pixels SPX may be differentiated or optimized according to the light emitting characteristics or target brightness of each light emitting element LE and/or sub-pixel SPX.

In addition, in FIG. 11, the pixel electrodes PXE are illustrated as being located only inside each light emitting area EA, but the present disclosure is not limited thereto. For example, at least a portion of one pixel electrode PXE may be arranged in a non-light emitting area around the light emitting area EA. For example, the sizes, shapes, and/or arrangement directions of the pixel electrodes PXE may vary depending on the embodiments.

In one or more embodiments, the sub-pixels SPX of each pixel PX may be arranged along the first direction DR1. Further, the sub-pixels SPX of each pixel PX may share one common electrode CE. For example, the common electrode CE extends in the first direction DR1 in each horizontal line of the display area DA, and sub-pixels SPX of pixels PX arranged in the corresponding horizontal line may share one common electrode CE.

The first sub-pixel SPX1 may include a first pixel electrode PXE1, a first light emitting element LE1, and a common electrode CE (or a portion of the common electrode CE) arranged in a first light emitting area EA1. The first light emitting area EA1 may refer to the light emitting area EA of the first sub-pixel SPX1. The first light emitting element LE1 may refer to the light emitting element LE of the first sub-pixel SPX1.

The second sub-pixel SPX2 may include a second pixel electrode PXE2, a second light emitting element LE2, and a common electrode CE arranged in a second light emitting area EA2. The second light emitting area EA2 may refer to the light emitting area EA of the second sub-pixel SPX2. The second light emitting element LE2 may refer to the light emitting element LE of the second sub-pixel SPX2.

The third sub-pixel SPX3 may include a third pixel electrode PXE3, a third light emitting element LE3, and a common electrode CE arranged in a third light emitting area EA3. The third light emitting area EA3 may refer to the light emitting area EA of the third sub-pixel SPX3. The third light emitting element LE3 may refer to the light emitting element LE of the third sub-pixel SPX3.

In each pixel PX, the first pixel electrode PXE1, the second pixel electrode PXE2, and the third pixel electrode PXE3 may be arranged along the first direction DR1. The first pixel electrode PXE1, the second pixel electrode PXE2, and the third pixel electrode PXE3 may be spaced (e.g., spaced apart) from the common electrode CE in the second direction DR2.

The pixel electrodes PXE may be electrically connected to the respective pixel circuits PXC through the respective pixel connection holes CT1, CT2, and CT3. For example, the first pixel electrode PXE1 may be electrically connected to the first pixel circuit PXC1 through the first pixel connection hole CT1. The second pixel electrode PXE2 may be electrically connected to the second pixel circuit PXC2 through the second pixel connection hole CT2. The third pixel electrode PXE3 may be electrically connected to the third pixel circuit PXC3 through the third pixel connection hole CT3.

The light emitting elements LE may be arranged between the respective pixel electrodes PXE and the common electrode CE. For example, the first light emitting element LE1 is arranged on the first pixel electrode PXE1 and the common electrode CE, and a portion of the first light emitting element LE1 may overlap the first pixel electrode PXE1 and another portion of the first light emitting element LE1 may overlap the common electrode CE. The first light emitting element LE1 may be electrically connected between the first pixel electrode PXE1 and the common electrode CE. The second light emitting element LE2 is arranged on the second pixel electrode PXE2 and the common electrode CE, and a portion of the second light emitting element LE2 may overlap the second pixel electrode PXE2 and another portion of the second light emitting element LE2 may overlap the common electrode CE. The second light emitting element LE2 may be electrically connected between the second pixel electrode PXE2 and the common electrode CE. The third light emitting element LE3 is arranged on the third pixel electrode PXE3 and the common electrode CE, and a portion of the third light emitting element LE3 may overlap the third pixel electrode PXE3 and another portion of the third light emitting element LE3 may overlap the common electrode CE. The third light emitting element LE3 may be electrically connected between the third pixel electrode PXE3 and the common electrode CE.

Each of the light emitting elements LE may emit light of a specific color (e.g., red light, green light, blue light, or white light). In one or more embodiments, the first light emitting element LE1, the second light emitting element LE2, and the third light emitting element LE3 may emit light of different colors. For example, the first light emitting element LE1, the second light emitting element LE2, and the third light emitting element LE3 may emit light of a first color (e.g., red light), light of a second color (e.g., green light), and light of a third color (e.g., blue light), respectively.

In one or more embodiments, the light emitting elements LE of at least two sub-pixels SPX may have different sizes. For example, the size of the first light emitting element LE1 may be larger than the sizes of each of the second light emitting element LE2 and the third light emitting element LE3.

In one or more embodiments, the light emitting elements LE may have differentiated or optimized sizes depending on the luminous efficiency of the light emitting elements LE, etc. For example, at least two of the light emitting elements LE from among, the first light emitting element LE1, the second light emitting element LE2, and the third light emitting element LE3 may have different sizes, depending on the luminous efficiency of each of , the first light emitting element LE1, the second light emitting element LE2, and the third light emitting element LE3. For example, when the luminous efficiency of the first light emitting element LE1 is lower than the luminous efficiency of each of the second light emitting element LE2 and the third light emitting element LE3 based on the same size and shape, the size of the first light emitting element LE1 may be larger than the sizes of each of the second light emitting element LE2 and the third light emitting element LE3. Accordingly, the luminous efficiency of the first light emitting element LE1 may be improved, and the difference in the luminous efficiency of the first light emitting element LE1, the second light emitting element LE2, and the third light emitting element LE3 may be reduced or prevented.

In one or more embodiments, the first light emitting element LE1, the second light emitting element LE2, and the third light emitting element LE3 may emit light of the same color. In this case, at least one of a light conversion layer (e.g., a light conversion layer including wavelength conversion particles such as quantum dots) and a color filter may be arranged on the light emitting element LE of at least one of the first sub-pixel SPX1, the second sub-pixel SPX2, and the third sub-pixel SPX3 to convert light emitted from the light emitting element LE of the corresponding sub-pixel SPX into light corresponding to an emission color of the corresponding sub-pixel SPX. When the first light emitting element LE1, the second light emitting element LE2, and the third light emitting element LE3 emit light of the same color, the sizes of the first light emitting element LE1, the second light emitting element LE2, and the third light emitting element LE3 may be the same or different from each other. For example, depending on the light conversion efficiency by the light conversion layer, at least one of the size of the light emitting elements LE of the sub-pixels SPX and the area of the light emitting areas EA of the sub-pixels SPX may be differentiated.

On the other hand, although FIG. 11 illustrates an embodiment in which each of the first sub-pixel SPX1, the second sub-pixel SPX2, and the third sub-pixel SPX3 includes a single light emitting element LE, the present disclosure is not limited thereto. For example, at least one of the first sub-pixel SPX1, the second sub-pixel SPX2, and the third sub-pixel SPX3 may include a plurality of light emitting elements LE.

The common electrode CE may be electrically connected to the second power supply lines VSL. For example, the common electrode CE may be electrically connected to the second power supply lines VSL through the pixel connection hole CT4 within the display area DA but is not limited thereto. A second driving voltage VSS may be applied to the common electrode CE and the second power supply lines VSL.

The pixel connection hole CT4 may be spaced (e.g., spaced apart) from the light emitting elements LE by a suitable distance (e.g., a predetermined distance) or more. For example, the distance d between the first light emitting element LE1 closest to the pixel connection hole CT4 and the pixel connection hole CT4 may be approximately 10 µm or more. In one or more embodiments, the shortest distance d between the pixel connection hole CT4 and the light emitting elements LE may be set to approximately 11 µm in consideration of alignment errors that may occur during the manufacturing process of the display panel 100.

By securing the distance between the pixel connection hole CT4 and the light emitting elements LE, each light emitting element LE may be more stably arranged in the pixels PX. For example, by controlling the distance between the pixel connection hole CT4 and the light emitting elements LE to 10 µm or more (e.g., 11 µm), the common electrode CE may be substantially flat in the area where the light emitting elements LE are arranged. Accordingly, the light emitting elements LE may be stably arranged or bonded on the common electrode CE.

In one or more embodiments, (e.g., as shown in FIG. 2) the first power supply bus line VSLB1 branched from the second power supply line VSL may be arranged right around the display area DA. For example, at least a portion of the first power supply line VSL may be arranged between the display area DA and at least one scan driving portion SDC1 and SDC2. For example, at least a portion of the first power supply bus line VSLB1 arranged on the left and right sides of the display area DA may be arranged between the display area DA and the first scan driving portion SDC1, and between the display area DA and the second scan driving portion SDC2.

The second power supply line VSL may be electrically connected to at least one pad PD arranged in the pad area PA. For example, the second power supply line VSL may extend to both sides of the non-display area NDA and the sub-area SBA below the display area DA and may be electrically connected to a plurality of pads PD arranged at both ends of the pad area PA. The second power supply line VSL may be electrically connected to the plurality of pads PD as a single integrated power supply line but may be formed as separate patterns and electrically connected to each other. At least one pad PD connected to the second power supply line VSL may be a power pad to which a second driving voltage VSS is applied. The connection structure between the second power supply line VSL and the pad PD is not limited to the above-described embodiment and may vary according to embodiments.

In one or more embodiments, the first power bus supply line VSLB1 may be arranged on the left/right and top sides of the display area DA to be around (e.g., surround) three sides of the display area DA. In one or more embodiments, the first power supply bus line VSLB1 may be arranged on the left/right sides of the display area DA to be around (e.g., to surround) the left and right sides of the display area DA. In one or more embodiments, the first power supply bus line VSLB1 may be arranged on the left/right and top/bottom sides of the display area DA to be around (e.g., to surround) four sides of the display area DA.

In one or more embodiments, the second power supply bus line VSLB2 branched from the second power supply line VSL may be arranged on the outside of the scan driving portion SDC1 and SDC2 to be around (e.g., to surround) the display area DA entirely. For example, the second power supply bus line VSLB2 may be arranged on the left/right and top sides of the display area DA to be around (e.g., to surround) three sides of the display area DA. For example, the second power supply bus line VSLB2 may have a shape corresponding to the display area DA and may be around (e.g., may surround) the display area DA.

The first power supply bus line VSLB1 and the second power supply bus line VSLB2 may completely surround the scan driving portion SDC1 and SDC2. For example, the first power supply bus line VSLB1 may be arranged on the right and bottom sides of the first scan driving portion SDC1, and the second power supply bus line VSLB2 may be arranged on the left and top sides of the first scan driving portion SDC1. Therefore, the top, bottom, left, and right sides of the first scan driving portion SDC1 may be completely surrounded by the first power supply bus line VSLB1 and the second power supply bus line VSLB2. Similarly, for example, the first power supply bus line VSLB1 may be arranged on the left and bottom side of the second scan driving portion SDC2, and the second power supply bus line VSLB2 may be arranged on the right and top side of the second scan driving portion SDC2. Therefore, the top, bottom, left, and right sides of the second scan driving portion SDC2 may be completely surrounded by the first power supply bus line VSLB1 and the second power supply bus line VSLB2.

Accordingly, damage to the circuits of the scan driving portions SDC1 and SDC2 from static electricity may be prevented.

FIG. 12 is a cross-sectional view illustrating an example of a cross-section of a display panel corresponding to the line X1-X1’ of FIG. 11. For example, FIG. 12 illustrates an example of a cross-section of the display panel 100 corresponding to a portion of a first sub-pixel SPX1. In one or more embodiments, the first sub-pixel SPX1, the second sub-pixel SPX2, and the third sub-pixel SPX3 may have substantially the same or similar cross-sectional structures. For example, corresponding circuit elements of the first sub-pixel SPX1, the second sub-pixel SPX2, and the third sub-pixel SPX3 (e.g., the second transistors T2 of the first sub-pixel SPX1, the second sub-pixel SPX2, and the third sub-pixel SPX3) may be arranged in substantially the same layer and may have substantially the same or similar cross-sectional structures.

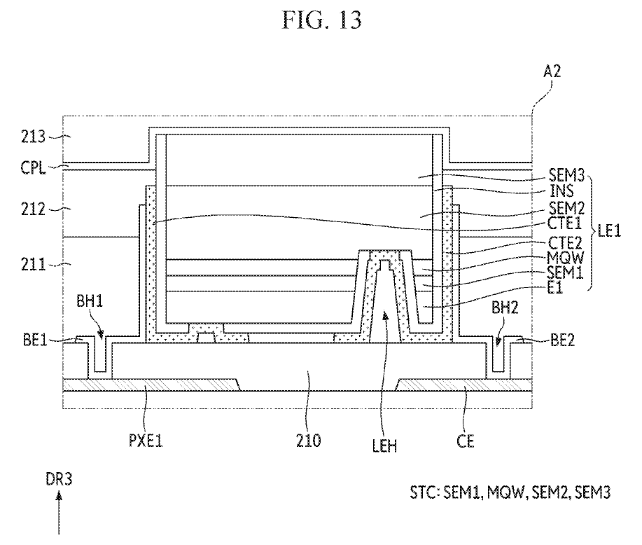

FIG. 13 is a cross-sectional view illustrating area A2 of FIG. 12 in detail. In one or more embodiments, the first light emitting element LE1, the second light emitting element LE2, and the third light emitting element LE3 may have substantially the same or similar cross-sectional structures as each other.

Referring to FIGS. 12 and 13, the display device 10 may include a plurality of light emitting elements LE, a second transistor TFT2, a capping layer CPL, and a color filter CF arranged in the display area DA. In one or more embodiments, the second transistor TFT2 may have a cross-sectional structure substantially the same or similar to cross-sectional structure as the first transistor TFT1.

A light emitting element layer may be arranged on the second planarization organic film 180. The light emitting element layer may include pixel electrodes PXE1, PXE2, and PXE3 included in the sub-pixels SPX, light emitting elements LE, a common electrode CE, and a first organic layer 210. Further, the light emitting element layer may further include a plurality of organic layers. The plurality of organic layers may include a second organic layer 211, a third organic layer 212, a capping layer CPL, a fourth organic layer 213, and a fifth organic layer 214.

A pixel electrode layer including pixel electrodes PXE1, PXE2, and PXE3 included in the sub-pixels SPX may be arranged on the second planarization organic film 180. In one or more embodiments, the light emitting element LE may be a flip-chip type micro LED. The flip-chip type micro LED refers to an LED in which first and second contact electrodes CTE1 and CTE2 are formed on one surface (e.g., a bottom surface) of the light emitting element LE. When the light emitting element LE is a flip-chip type micro LED, the pixel electrode layer may further include a common electrode CE. For example, the pixel electrodes PXE and the common electrode CE of the sub-pixels SPX may be arranged on (e.g., at) the same layer and may be formed concurrently (e.g., simultaneously) using the same conductive material.

Each of the first pixel electrode PXE1, the second pixel electrode PXE2, and the third pixel electrode PXE3 may be connected to the second source connection electrode PCE2 through a connection hole (CT1/CT2/CT3 of FIG. 11) penetrating the second planarization organic film 180. Each of the pixel electrodes PXE1, PXE2, and PXE3 may be connected to a first source region S1 or a first drain region D1 of the thin-film transistor TFT1 through the first source connection electrode PCE1 and the second source connection electrode PCE2. Therefore, a voltage controlled by the thin-film transistor TFT1 may be applied to each of the pixel electrodes PXE1, PXE2, and PXE3.

The common electrode CE may be connected to a second power supply line (VSL of FIG. 4) to which a second driving voltage (VSS of FIG. 3) is applied through a common connection hole. Therefore, the second driving voltage VSS may be applied to the common electrode CE.

In one or more embodiments, the patterns of the pixel electrode layer (e.g., the pixel electrodes PXE and the common electrode CE) may include the same conductive material. In one or more embodiments, the patterns of the pixel electrode layer (e.g., the pixel electrodes PXE and the common electrode CE) may include the same conductive material. In one or more embodiments, the patterns of the pixel electrode layer include a metal (e.g., at least one of molybdenum (Mo), aluminum (Al), chromium (Cr), gold (Au), titanium (Ti), nickel (Ni), neodymium (Nd), copper (Cu), and/or other metals, and/or alloys thereof) and may have a single-layer or multi-layer structure. For example, the patterns of the pixel electrode layer may be low-resistance patterns formed with a triple-layer structure of titanium/aluminum/titanium (Ti/Al/Ti). Alternatively, the patterns of the pixel electrode layer may include other low-resistance materials (e.g., copper (Cu)) and/or structures. When the resistance of the patterns included in the pixel electrode layer is reduced or minimized, the first driving voltage VDD and the second driving voltage VSS may be stably transmitted to the light emitting elements LE of the sub-pixels SPX.

A first organic layer 210 may be arranged on the pixel electrodes PXE and the common electrode CE. The first organic layer 210 temporarily fixes or adheres the light emitting elements LE to prevent the light emitting elements LE from tilting and falling over during the process of transferring the light emitting elements LE to the display panel 100. For example, the first organic layer 210 may be a film for temporarily bonding the light emitting elements LE onto each of the pixel electrodes PXE and the common electrode CE. To facilitate bonding, the thickness of the first organic layer 210 may be greater than the thickness of each of the pixel electrodes PXE and the common electrode CE, and greater than the thickness of each of the first and second contact electrodes CTE1 and CTE2 of the light emitting elements LE.

FIG. 12 illustrates the first organic layer 210 being arranged entirely over the display area DA, but the present disclosure is not limited thereto. For example, the first organic layer 210 may be arranged only on a portion of the pixel electrodes PXE and the common electrode CE that overlap the light emitting elements LE and may expose other portions of the pixel electrodes PXE and the common electrode CE.

The first organic layer 210 may include at least one insulating material, such as an organic insulating material. For example, the first organic layer 210 may be a photosensitive organic film such as a photoresist. Alternatively, the first organic layer 210 may be formed from an acrylic resin, an epoxy resin, a phenolic resin, a polyamide resin, and/or a polyimide resin, and/or the like.

The light emitting elements LE may be arranged on the first organic layer 210. For example, a first light emitting element LE1 may be arranged on the first pixel electrode PXE1 and the common electrode CE of the first sub-pixel SPX1. A second light emitting element LE2 may be arranged on the second pixel electrode PXE2 and the common electrode CE of the second sub-pixel SPX2. A third light emitting element LE3 may be arranged on the third pixel electrode PXE3 and the common electrode CE of the third sub-pixel SPX3.

In one or more embodiments, each of the light emitting elements LE may be a micro LED including an inorganic material. For example, each of the light emitting elements LE may be formed of an inorganic material such as gallium nitride (GaN), and the length of each of the light emitting elements LE in the first direction DR1, the length of each of the light emitting elements LE in the second direction DR2, and the length of each of the light emitting elements LE in the third direction DR3 may be several µm to several hundred µm, respectively. For example, the length of each of the light emitting elements LE in the first direction DR1, the length of each of the light emitting elements LE in the second direction DR2, and the length of each of the light emitting elements LE in the third direction DR3 may be approximately 100 µm or less.

The light emitting elements LE may be formed by growing on a semiconductor substrate such as a silicon substrate or a sapphire substrate. The light emitting elements LE may be transferred directly from the semiconductor substrate onto the pixel electrodes PXE and the common electrode CE of the display panel 100. Alternatively, the light emitting elements LE may be transferred onto the pixel electrodes PXE and the common electrode CE of the display panel 100 by an electrostatic method using an electrostatic head or a stamp method using an elastic polymer material such as PDMS or silicon as a transfer substrate.

The light emitting element LE may include a conductive layer E1, a semiconductor stack STC, contact electrodes CTE1 and CTE2, and a protective film INS . The semiconductor stack STC may include a first semiconductor layer SEM1, an active layer MQW (e.g., a light emitting layer), and a second semiconductor layer SEM2 sequentially arranged in the third direction DR3. In one or more embodiments, as shown in FIG. 13, the semiconductor stack STC may further include a third semiconductor layer SEM3 on the second semiconductor layer SEM2.

The conductive layer E1 may be arranged on a bottom surface of the first semiconductor layer SEM1. In FIG. 13, the conductive layer E1 is illustrated as covering the entire bottom surface of the first semiconductor layer SEM1, but the present disclosure is not limited thereto. In one or more embodiments, the conductive layer E1 may be arranged on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu), and/or a transparent conductive material such as a metal oxide.

The first semiconductor layer SEM1 may be arranged on the conductive layer E1. The first semiconductor layer SEM1 may be formed of a semiconductor material layer doped with a first conductive dopant such as magnesium (Mg), zinc (Zn), calcium (Ca), strontium (Sr), barium (Ba), and/or the like, for example, gallium nitride (GaN).

The active layer MQW may be arranged on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include gallium nitride (GaN), indium gallium nitride (InGaN), and/or aluminum gallium nitride (AlGaN).

The active layer MQW may emit light by recombination of electron-hole pairs in response to an electric signal applied through the first semiconductor layer SEM1 and the second semiconductor layer SEM2. The active layer MQW may include a material having a single or multiple quantum well structure. When the active layer MQW includes a material having a multiple quantum well structure, it may have a structure in which a plurality of well layers and barrier layers are alternately laminated. In this case, the well layer may be formed of InGaN, and the barrier layer may be formed of GaN and/or AlGaN but is not limited thereto. Alternatively, the active layer MQW may have a structure in which semiconductor materials having a large band gap energy and semiconductor materials having a small band gap energy are alternately laminated or may include other Group III to Group V semiconductor materials depending on the wavelength of the light emitted.

When the active layer MQW includes indium gallium nitride (InGaN), the color of the light emitted may vary depending on the content of indium (In). For example, as the content of indium (In) increases, the wavelength band of the light emitted by the active layer may shift to the red wavelength band, and as the content of indium (In) decreases, the wavelength band of the light emitted by the active layer may shift to the blue wavelength band. For example, the content of indium (In) in the active layer MQW of the light emitting element LE that emits light of a third color (e.g., blue light) may be approximately 10 wt% to 20 wt%.

The second semiconductor layer SEM2 may be arranged on the active layer MQW. The second semiconductor layer SEM2 may be a semiconductor material layer doped with a second conductive dopant such as silicon (Si), germanium (Ge), and/or tin (Sn), for example, gallium nitride (GaN).

The third semiconductor layer SEM3 may be arranged on the second semiconductor layer SEM2. The third semiconductor layer SEM3 may be a semiconductor material layer in which an n-type dopant is lower than a suitable threshold value (.g., a predetermined threshold value) and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) in which an n-type dopant is lower than a suitable threshold value (e.g., a predetermined threshold value).

An electron blocking layer may be arranged between the first semiconductor layer SEM1 and the active layer MQW. The electron blocking layer may be a layer for suppressing or preventing too many electrons from flowing into the active layer MQW. For example, the electron blocking layer may be AlGaN or p-AlGaN doped with p-type Mg. The electron blocking layer may be omitted.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

A protective film INS may be arranged on the side surface of the conductive layer E1, the side surface of the first semiconductor layer SEM1, the side surface of the active layer MQW, the side surface of the second semiconductor layer SEM2, and the side surface of the third semiconductor layer SEM3. The protective film INS may be a film for protecting the side surface of the light emitting element LE. The protective film INS may be formed of an inorganic material, such as silicon nitride (SiNₓ), silicon oxide (SiOₓ), silicon oxynitride (SiON), titanium oxide (TiOₓ), aluminum oxide (AlOₓ), or other inorganic insulating material.

In FIG. 13, the protective film INS is shown as an example as being arranged on the side surfaces of the first semiconductor layer SEM1, the side surfaces of the active layer MQW, and the side surfaces of the second semiconductor layer SEM2, and the side surface of the third semiconductor layer SEM3 of the semiconductor stack STC, but the present disclosure is not limited thereto. For example, the protective film INS may be arranged on the side surfaces of the first semiconductor layer SEM1, the side surfaces of the active layer MQW, and the side surfaces of the second semiconductor layer SEM2 of the semiconductor stack STC.

A hole LEH may be formed that penetrates the conductive layer E1, the first semiconductor layer SEM1, and the active layer MQW of the light emitting element LE to expose the second semiconductor layer SEM2. The hole LEH may have a circular planar shape, but the present disclosure is not limited thereto. For example, the hole LEH may have a planar shape of a polygon, such as an ellipse, or a rectangle.

The protective film INS may be arranged on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Accordingly, the second semiconductor layer SEM2 may be exposed without being covered by the protective film INS .

The first contact electrode CTE1 may be arranged on at least one side surface of the semiconductor stack STC, and at least one side surface and the bottom surface of the conductive layer E1. The first contact electrode CTE1 may be arranged on the bottom surface of the conductive layer E1 exposed without being covered by the protective film INS . Therefore, the first contact electrode CTE1 may be electrically connected to the conductive layer E1.

The second contact electrode CTE2 may be arranged on at least one side of the semiconductor stack STC and at least one side and the bottom surface of the conductive layer E1. At this time, the first contact electrode CTE1 may be arranged on the first side of the semiconductor stack STC and the first side of the conductive layer E1, while the second contact electrode CTE2 may be arranged on the second side of the semiconductor stack STC and the second side of the conductive layer E1.

The second contact electrode CTE2 may be arranged on the protective film INS arranged in the hole LEH and the second semiconductor layer SEM2 exposed in the hole LEH without being covered by the protective film INS . Therefore, the second contact electrode CTE2 may be electrically connected to the second semiconductor layer SEM2 in the hole LEH.

FIGS. 12 and 13 illustrate that the first contact electrode CTE1 and the second contact electrode CTE2 of each of the light emitting elements LE are arranged on the first organic layer 210, but the present disclosure is not limited thereto. For example, the first organic layer 210 may be arranged on a portion of the bottom surface and side surface of the first contact electrode CTE1 and a portion of the bottom surface and side surface of the second contact electrode CTE2 of each of the light emitting elements LE. Alternatively, the first organic layer 210 may be arranged on the side surfaces of the conductive layer E1 of each of the light emitting elements LE. Alternatively, the first organic layer 210 may be arranged on the side surfaces of the first semiconductor layer SEM1, the side surfaces of the active layer MQW, and the side surfaces of the second semiconductor layer SEM2 of each of the light emitting elements LE. In this case, the first organic layer 210 may be arranged on a portion of each of the side surfaces of the second semiconductor layer SEM2.

The first contact electrode CTE1 and the second contact electrode CTE2 may each be arranged on three side surfaces of the semiconductor stack STC. For example, when the semiconductor stack STC includes first to fourth side surfaces, the first contact electrode CTE1 may be arranged on the first side, the second side, and the third side, and the second contact electrode CTE2 may be arranged on the second side, the third side, and the fourth side.

The first contact electrode CTE1 and the second contact electrode CTE2 may include at least one conductive material, for example, molybdenum (Mo), aluminum (Al), chromium (Cr), gold (Au), titanium (Ti), nickel (Ni), neodymium (Nd), and/or copper (Cu). In one or more embodiments, the first contact electrode CTE1 and the second contact electrode CTE2 may be formed from a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

When each of the first contact electrode CTE1 and the second contact electrode CTE2 is formed of a metal having a high reflectivity, light emitted from the active layer MQW of the light emitting element LE and traveling in the lateral direction of the light emitting element LE may be reflected by the first contact electrode CTE1 and the second contact electrode CTE2 and may be emitted to the top surface of the light emitting element LE. Therefore, because the loss of light from the light emitting element LE may be reduced, the light efficiency of the light emitting element LE may be increased. To increase the light efficiency of the light emitting element LE, the first contact electrode CTE1 and the second contact electrode CTE2 may be arranged to cover most of the side surface of the semiconductor stack STC.

A first connection electrode BE1 connects the first contact electrode CTE1 of the light emitting element LE and each pixel electrode PXE. For example, the first connection electrode BE1 of the first sub-pixel SPX1 may connect the first contact electrode CTE1 of the first light emitting element LE1 and the first pixel electrode PXE1. Similarly, the first connection electrode BE1 of the second sub-pixel SPX2 may connect the first contact electrode CTE1 of the second light emitting element LE2 and the second pixel electrode PXE2, and the first connection electrode BE1 of the third sub-pixel SPX3 may connect the first contact electrode CTE1 of the third light emitting element LE3 and the third pixel electrode PXE3.

The first connection electrode BE1 may be connected to each pixel electrode PXE exposed through the first connection hole BH1 penetrating the first organic layer 210. In addition, the first connection electrode BE1 may be arranged on the top surface of the first organic layer 210 and the first contact electrode CTE1 of the light emitting element LE. In one or more embodiments, if the first organic layer 210 is arranged only on a portion of the pixel electrode PXE overlapping the light emitting element LE, the first connection hole BH1 may be unnecessary. For example, the first connection electrode BE1 may be arranged directly on the pixel electrode PXE exposed around the light emitting element LE.

A second connection electrode BE2 connects the second contact electrode CTE2 of the light emitting element LE and the common electrode CE. For example, the second connection electrode BE2 of the first sub-pixel SPX1 may connect the second contact electrode CTE2 of the first light emitting element LE1 and the common electrode CE. Similarly, the second connection electrode BE2 of the second sub-pixel SPX2 may connect the second contact electrode CTE2 of the second light emitting element LE2 and the common electrode CE, and the second connection electrode BE2 of the third sub-pixel SPX3 may connect the second contact electrode CTE2 of the third light emitting element LE3 and the common electrode CE. In one or more embodiments, if the first organic layer 210 is arranged only on a portion of the common electrode CE overlapping the light emitting element LE, the second connection hole BH2 may be unnecessary. For example, the second connection electrode BE2 may be arranged directly on the common electrode CE exposed around the light emitting element LE.

Each of the first connection electrode BE1 and the second connection electrode BE2 may include at least one conductive material, for example, molybdenum (Mo), aluminum (Al), chromium (Cr), gold (Au), titanium (Ti), nickel (Ni), neodymium (Nd), and/or copper (Cu). Alternatively, each of the first connection electrode BE1 and the second connection electrode BE2 may be made of a transparent conductive material such as indium tin oxide (ITO) and/or indium zinc oxide (IZO) (e.g., transparent conductive oxide (TCO)).

When of the first connection electrode BE1 and the second connection electrode BE2 is made of a metal material having a high reflectivity such as aluminum (Al), light emitted from the active layer MQW of the light emitting element LE and traveling in the lateral direction of the light emitting element LE may be reflected by the connection electrodes BE and traveling in the upper direction of the light emitting element LE. Accordingly, because the light loss of the light emitting element LE may be reduced, the light efficiency of the light emitting element LE may be increased.

As shown in FIGS. 12 and 13, the conductive layer E1 of the light emitting element LE may be electrically connected to each pixel electrode PXE through the first contact electrode CTE1 and the first connection electrode BE1. Further, the second semiconductor layer SEM2 of the light emitting element LE may be electrically connected to the common electrode CE through the second contact electrode CTE2 formed in the hole LEH and the second connection electrode BE2. Meanwhile, the pixel electrodes PXE may be referred to as an anode electrode or a first electrode, and the common electrode CE may also be referred to as a cathode electrode or a second electrode.

The second organic layer 211 may be arranged on the first organic layer 210. The second organic layer 211 may be arranged to cover a portion of the side surface of the light emitting element LE. Further, the second organic layer 211 may expose a portion of the first connection electrode BE1 and the second connection electrode BE2 without being covered by the second organic layer 211.

The third organic layer 212 may be arranged on the second organic layer 211. The third organic layer 212 may be arranged to cover a portion of the side surface of each of the light emitting elements LE. The third organic layer 212 may be arranged on at least a portion of the first and second connection electrodes BE1 and BE2 that are exposed without being covered by the second organic layer 211. The top surface of each of the light emitting elements LE may be exposed without being covered by the third organic layer 212.

The second organic layer 211 and the third organic layer 212 are layers for leveling the steps caused by the plurality of light emitting elements LE. When the height of the second organic layer 211 is arranged to cover most of the sides of each of the plurality of light emitting elements LE, the third organic layer 212 may be omitted.

The second organic layer 211 and the third organic layer 212 may include at least one insulating material, such as an organic insulating material. For example, each of the second organic layer 211 and the third organic layer 212 may be formed of an organic film, such as an acrylic resin, an epoxy resin, a phenolic resin, a polyamide resin, a polyimide resin, and/or the like.

The capping layer CPL may be arranged on the light emitting elements LE, the second organic layer 211, and the third organic layer 212. The capping layer CPL may include at least one insulating material, for example, an inorganic insulating material.

In one or more embodiments, if the light emitting elements LE of each of the sub-pixels SPX emit light of a color corresponding to (e.g., matching) the emission color (or emission wavelength) of the corresponding sub-pixel SPX, the display panel 100 may not include a light conversion layer. For example, the fourth organic layer 213 may be arranged directly on the capping layer CPL.

If the sub-pixels SPX include light emitting elements LE that emit light corresponding to their respective emission colors, the light emitted from the light emitting elements LE may be utilized more efficiently. For example, the reduction in the light efficiency of the sub-pixels SPX due to light conversion may be prevented. Furthermore, the color purity of the light emitted from the sub-pixels SPX may be increased, and the color reproducibility of the sub-pixels SPX may be increased.

In one or more embodiments, when the light emitting element LE of at least one sub-pixel SPX emits light of a different color from the emission color (or emission wavelength) of the corresponding sub-pixel SPX, a light conversion layer may be further arranged on the light emitting element LE. For example, when the first light emitting element LE1 emits blue light and the first sub-pixel SPX1 is a red sub-pixel that emits red light, a light conversion layer covering the first light emitting element LE1 may be arranged on the capping layer CPL. The light conversion layer may include light conversion particles (e.g., red quantum dots, etc.) that convert blue light incident from the first light emitting element LE1 into red light. When the sub-pixels SPX include light emitting elements LE that emit light of the same color, the manufacturing efficiency of the light emitting element layer and the display panel 100 including the light emitting element layer may be increased, and the manufacturing cost may be reduced.

The fourth organic layer 213 may be arranged on the capping layer CPL (or light conversion layer). The fourth organic layer 213 may be an organic film including an organic insulating material (e.g., acrylic resin, epoxy resin, phenolic resin, polyamide resin, or polyimide resin), and the top surface of the fourth organic layer 213 may be substantially flat. However, the present disclosure is not limited thereto. The fourth organic layer 213 may be formed to a sufficient thickness to include a substantially flat top surface or may be flattened through a separate flattening process. Accordingly, the top surface of the fourth organic layer 213 may be substantially flat.

The color filter CF may be arranged on the fourth organic layer 213. The color filter CF may further include a color filter CF arranged in the light emitting areas EA of the sub-pixels SPX, and a fifth organic layer 214 covering the color filter CF.

The color filter CF may include color filters CF that selectively transmit light corresponding to the light emitting color (or light emitting wavelength) of each of the sub-pixels SPX. For example, when the first sub-pixel SPX1, the second sub-pixel SPX2, and the third sub-pixel SPX3 are sub-pixels SPX that emit red light, green light, and blue light, respectively, a red color filter, a green color filter, and a blue color filter may be arranged in the first light emitting area EA1 of the first sub-pixel SPX1, the second light emitting area EA2 of the second sub-pixel SPX2, and the third light emitting area EA3 of the third sub-pixel SPX3, respectively. In one or more embodiments, the color filters CF of the sub-pixels SPX may overlap each other in a non-light emitting area surrounding the light emitting areas EA of the sub-pixels SPX to form a light blocking pattern.

The fifth organic layer 214 may be arranged on the color filters CF. The fifth organic layer 214 may be an organic film including an organic insulating material, and the top surface of the fifth organic layer 214 may be substantially flat. However, the present disclosure is not limited thereto.

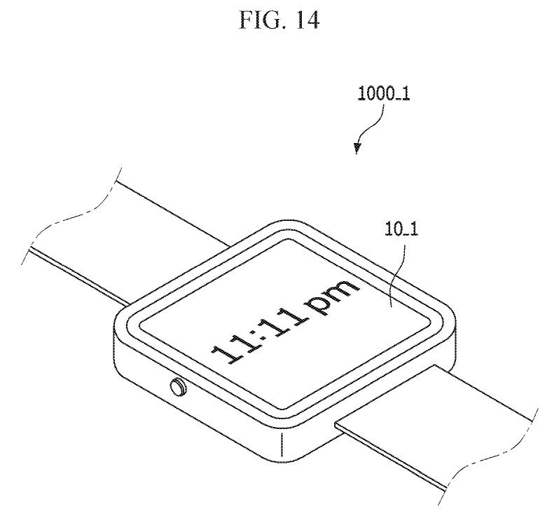

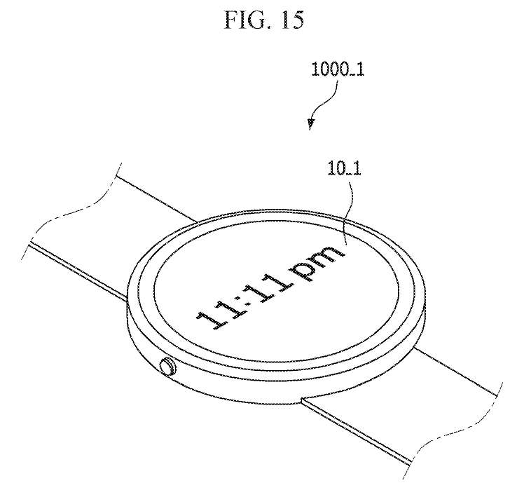

FIGS. 14 and 15 illustrate a smart watch including a display device according to one or more embodiments.

Referring to FIGS. 14 and 15, a display device 10_1 according to one or more embodiments may be applied to a smart watch 1000_1, which is one of smart devices.

The flat shape of the display device 10_1 may be a square or a circle but the present disclosure is not limited thereto and may be modified in various ways, such as an oval.

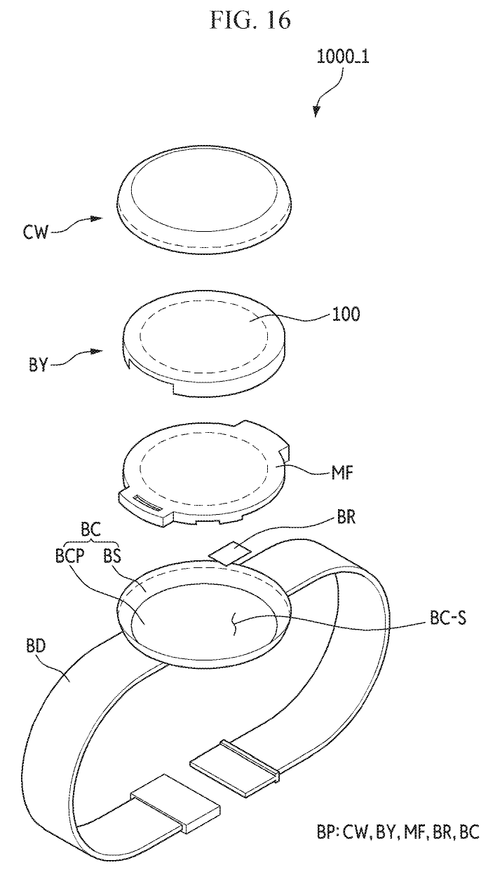

FIG. 16 is an exploded perspective view of a smart watch including a display device according to one or more embodiments.

Referring to FIG. 16, the smart watch 1000_1 may include a main body unit BP and a wearable portion BD.

The main body unit BP may include a display panel 100 on which an image is displayed, a cover window CW disposed on the display panel 100, a bottom cover BC disposed under the display panel 100, a middle frame MF disposed between the cover window CW and the bottom cover BC, and a battery BR disposed between the middle frame MF and the bottom cover BC. In addition to the battery BR, a main processor controlling the smart watch 1000_1, a communication chipset for wirelessly communicating with the outside, and a circuit board in which memory, etc. are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 10 to protect the display panel 10 and to transmit light emitted from the display panel 10. As described above, the cover window CW may include a light-blocking portion to block a portion of the light emitted from the display panel 10. The cover window CW may be made of a transparent plastic material, a glass material, or a reinforced glass material.

The cover window CW may be arranged to overlap the display panel 10 and cover the front of the display panel 10. The cover window CW generally has a shape similar to that of the display panel 10 in terms of a plane, but its size may be larger than that of the display panel 10. For example, the cover window CW may protrude outward from the display panel 10. The plane shape of the cover window CW may be the same as that of the main body unit BP. For example, the planar shape of the cover window CW may be generally circular but the present disclosure is not limited thereto and may have various shapes, for example, a polygon such as a square or an oval.

The middle frame MF is a joining member for joining the cover window CW and the bottom cover BC and is arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be generally flat.

The peripheral portion BS may be arranged to surround the central cover portion BCP. The peripheral portion BS may be a portion that is bent and curved from the central cover portion BCP. The peripheral portion BS may be bent from the edge of the central portion CP. In some embodiments, the peripheral portion BS may include a curved surface having a predetermined curvature, and the other portion may be flat. The degree (e.g., angle) at which the peripheral portion BS is bent from the central cover portion BCP may be an obtuse angle, but the present disclosure is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor or the like is mounted. The display device 10_1 may be electrically connected to the circuit board to receive digital video signals, timing signals, power, and the like.

The bottom cover BC is placed on the outermost rear surface of the electronic device and may include at least one of a plastic material, a metal material, and a glass material, and may include a color coating layer. For example, the bottom cover BC according to one example may be a flat glass having a transparent, translucent, or opaque color coating layer.

The bottom cover BC according to another example may have the same shape as the cover window CW and may include a glass material having a color coating layer. For example, the bottom cover BC according to another example may have a structure symmetrical to the cover window CW with a middle frame MF in between and may include a transparent, translucent, or opaque color coating layer.

The wearing portion BD is a portion for fixing the main body unit BP to the user's wrist, for example, and may be one of a strap, a chain, and a bracelet.

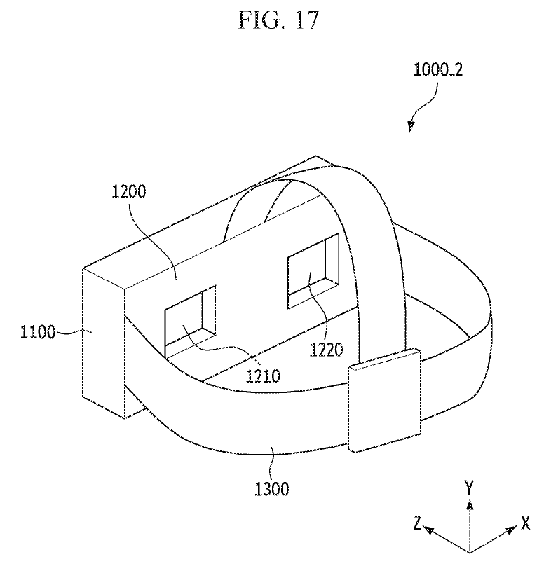

FIG. 17 illustrates a virtual reality (VR) device including a display device according to one or more embodiments.

Referring to FIG. 17, a head mounted display device 1000_2 according to one or more embodiments include a display device housing 1100, a housing cover 1200, a first eyepiece 1210, a second eyepiece 1220, and head mounted band 1300.

The display device housing 1100 houses a display device. a head mounted display device 1000_2 according to one or more embodiments further include a first optical member disposed between the first display device 10_2 and the first eyepiece 1210.

The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are disposed separately in FIG. 17, the present disclosure is not limited thereto. The first eyepiece 1210 and the second eyepiece 1220 may also be combined into one.

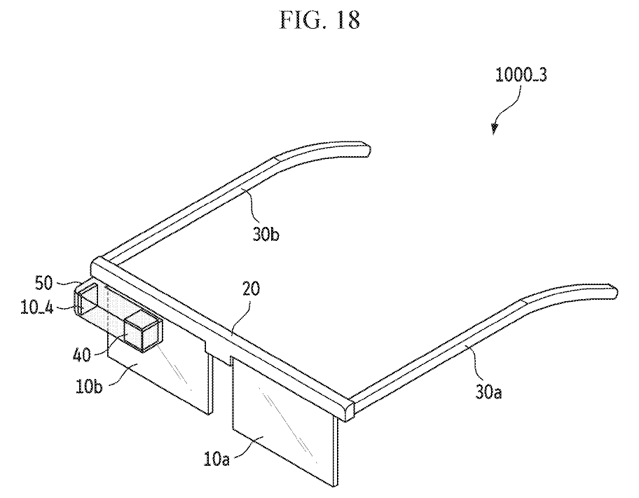

The head mounted band 1300 fixes the display device housing 1100 to a user’s head so that the first eyepiece 1210 and the second eyepiece 1220 of the housing cover 1200 are kept placed on the user’s left and right eyes, respectively. When the display device housing 1200 is implemented to be lightweight and small, the head mounted display device 1000_2 may include an eyeglass frame as illustrated in FIG. 18 instead of the head mounted band 1300.

The display device housing 1100 houses display device. In addition, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 18 illustrates a head-mounted display device including a display device according to one or more embodiments. FIG. 18 illustrates a VR device 1000_3 to which a display device 10_4 according to one or more embodiments has been applied.

Referring to FIG. 18, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 18, a case where the VR device 1000_3 is a glasses-type display device including the eyeglass frame legs 30a and 30b is illustrated as an example. In other words, the VR device 1000_3 according to the embodiment is not limited to the one illustrated in FIG. 18 and can be applied in various forms to various other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is disposed at a right end of the support frame 20 in FIG. 18, the present disclosure is not limited thereto. For example, the display device housing 50 may also be disposed at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. As another example, the display device housing 50 may be disposed at both the right end and the left end of the support frame 20. In this case, the user may view a VR image displayed on the display device 10_4 through both the left eye and the right eye.

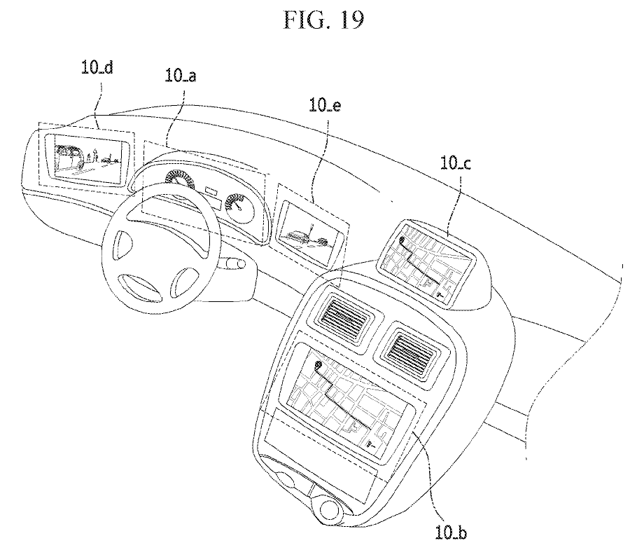

FIG. 19 illustrates an automobile instrument panel and center fascia including display devices according to one or more embodiments. FIG. 19 illustrates a vehicle to which display devices 10_a through 10_e according to one or more embodiments have been applied.

Referring to FIG. 19, the display devices 10_a through 10_c according to the embodiment may be applied to an instrument cluster of the vehicle, a center fascia of the vehicle, or a center information display (CID) disposed on a dashboard of the vehicle. In addition, the display devices 10_d and 10_e according to the embodiment may be applied to room mirror displays that replace side mirrors of the vehicle.

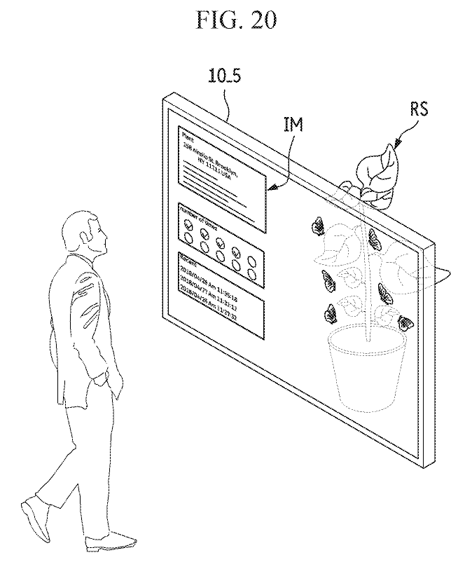

FIG. 20 illustrates a transparent display device including a display device according to one or more embodiments.

Referring to FIG. 20, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. When the display device 10_5 is applied to the transparent display device, a substrate of the display device 10_5 may include a light transmitting portion that can transmit light or may be made of a material that can transmit light.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate including a display area and a non-display area;
a plurality of pixels in the display area;
a scan driving portion configured to apply scan signals to the plurality of pixels and is located in the non-display area;
a first power supply bus line in the non-display area and is arranged closer to the display area than the scan driving portion is, the first power supply bus line being around the display area and electrically connected to the pixels; and
a second power supply bus line in the non-display area and is arranged farther from the display area than the scan driving portion is, the second power supply bus line being around the first power supply bus line,
wherein the first power supply bus line and the second power supply bus line are branched from one power supply line and are electrically connected to each other.

2. The display device of claim 1, wherein a top and bottom of the scan driving portion is completely surrounded by the first power supply bus line and the second power supply bus line.

3. The display device of claim 1, wherein a pixel of the plurality of pixels comprises:
a common electrode and a plurality of pixel electrodes on the substrate; and
a plurality of light emitting elements electrically connected between the plurality of pixel electrodes and the common electrode,
wherein the common electrode is electrically connected to the first power supply bus line.

4. The display device of claim 1, further comprising an anti-static circuit located on a top side of the display area,
wherein the anti-static circuit is located between the first power supply bus line and the second power supply bus line.

5. The display device of claim 1, further comprising a power supply connection electrode that connects the first power supply bus line and the second power supply bus line and covers an area between the scan driving portion and the first power supply bus line, and an area between the scan driving portion and the second power supply bus line, and covers the scan driving portion.

6. The display device of claim 5, wherein the power supply connection electrode has a plurality of hole patterns penetrating the power supply connection electrode in at least one of the scan driving portion, between the first power supply bus line and the scan driving portion, and between the scan driving portion and the second power supply bus line.

7. The display device of claim 6, wherein the power supply connection electrode is on a same layer as pixel electrodes and a common electrode in the plurality of pixels and is electrically connected to the common electrode.

8. The display device of claim 6, further comprising:
a first line connection electrode in the non-display area and located between the first power supply bus line and the power supply connection electrode, and
a second line connection electrode in the non-display area and located between the second power supply bus line and the power supply connection electrode.

9. The display device of claim 8, wherein a common electrode of the plurality of pixels is electrically connected to the second line connection electrode.

10. The display device of claim 1,
wherein the pixels are arranged along a first direction and a second direction in the display area,
wherein the pixels of each horizontal line arranged along the first direction among the pixels share one common electrode extending in the first direction,
wherein the common electrodes of the pixels arranged along the second direction among the pixels are arranged along the second direction.

11. The display device of claim 10,
wherein the second power supply bus lines branch from the first power supply bus line are arranged along the second direction in the display area, and extend in the first direction.

12. The display device of claim 11,
wherein the second power supply bus lines are electrically connected to adjacent common electrodes.

13. The display device of claim 11,
wherein the common electrode and the second power supply bus lines are electrically connected to each other through a through hole penetrating an organic layer between the common electrode and the second power supply bus lines.

14. The display device of claim 11,
wherein the plurality of pixels comprises a first pixel, a second pixel, and a third pixel arranged along the first direction in each pixel area in which each of the pixels is arranged.

15. The display device of claim 1, further comprising a sub-area protruding in a second direction from one side of the display area and the non-display area,
wherein the sub-area includes at least one pad configured to receive a driving voltage,
wherein the power supply line is a conductor electrically connected to the pad to transmit the driving voltage.

16. The display device of claim 1,
wherein the scan driving portion comprises a first scan driving portion on a first side of the display area and a second scan driving portion on a second side facing the first side,
wherein the first power supply bus line is located between the first scan driving portion and the display area and between the second scan driving portion and the display area.

17. The display device of claim 16,
wherein the second power supply bus line is located outside the first scan driving portion and the second scan driving portion.

18. The display device of claim 1, further comprising:
a write scan line connected to the plurality of pixels from the scan driving portion and configured to output a write scan signal;
a control scan line connected to the plurality of pixels from the scan driving portion and configured to output a control scan signal; and
an initialization scan line connected to the plurality of pixels from the scan driving portion and configured to output an initialization scan signal.

19. The display device of claim 18,
wherein the write scan line, the control scan line, and the initialization scan line overlap with the first power supply bus line.

20. An electronic device comprising:
a display device;
a window on the display device; and
a bottom cover below the display device,
wherein the display device comprises:
a substrate including a display area and a non-display area;
a plurality of pixels in the display area;
a scan driving portion configured to apply scan signals to the plurality of pixels and is located in the non-display area on a first side of the display area;
a first power supply bus line in the non-display area and is arranged closer to the display area than the scan driving portion is, the first power supply bus line being around the display area and electrically connected to the pixels; and
a second power supply bus line in the non-display area and arranged farther from the display area than the scan driving portion is, the second power supply bus line being around the first power supply bus line,
wherein the first power supply bus line and the second power supply bus line are branched from one power supply line and are electrically connected to each other.
